(19) United States
(12) Patent Application Publication
(10) Pub. No.: US 2024/0178093 A1
(43) Pub. Date: May 30, 2024

(54) SEMICONDUCTOR DEVICE, METHOD FOR MANUFACTURING SEMICONDUCTOR DEVICE, AND ELECTRONIC APPARATUS

(71) Applicant: SONY SEMICONDUCTOR SOLUTIONS CORPORATION, Kanagawa (JP)

(72) Inventor: Takayuki TANAKA, Kanagawa (JP)

(73) Assignee: SONY SEMICONDUCTOR SOLUTIONS CORPORATION, Kanagawa (JP)

(21) Appl. No.: 18/550,726

(22) PCT Filed: Mar. 15, 2022
(86) PCT No.: PCT/JP2022/011599

§ 371 Date: Sep. 15, 2023

(30) Foreign Application Priority Data
Mar. 25, 2021 (JP) 2021-052451

(51) Int. Cl. H01L 23/367; H01L 23/373; H05K 7/20

(52) U.S. Cl. CPC H01L 23/367; H01L 23/3736; H05K 7/20218; H05K 7/20436

(57) ABSTRACT

Provided are a semiconductor device configured to suppress a temperature rise of a semiconductor element and to suppress warpage, a method for manufacturing the semiconductor device including a cooling medium sealing step, and an electronic apparatus including the semiconductor device. The semiconductor device includes: a semiconductor element; a substrate to which the semiconductor element is adhered; and a cooling medium with which a clearance formed when the semiconductor element and the substrate are adhered to each other with an adhesive is filled. The cooling medium is a liquid metal, a metal-coated small sphere, or a liquid metal and a metal-coated small sphere. The cooling medium transmits heat generated by the semiconductor element to the outside to suppress a temperature rise.

### TECHNICAL FIELD

The present disclosure relates to a semiconductor device having a heat dissipation structure by a cooling medium in a semiconductor package, a method for manufacturing a semiconductor device having a cooling medium sealing step, and an electronic apparatus having the semiconductor device.

### BACKGROUND ART

Conventionally, with progress of miniaturization of semiconductor processes and an increase in speed of semiconductor elements, power consumption of semiconductor elements has increased, resulting in an increase in an amount of heat generated. The increase in the amount of heat generated in the semiconductor elements causes problems such as characteristic fluctuation and reliability deterioration. For this reason, semiconductor packages have been required to efficiently cool the semiconductor elements.

In the semiconductor package, in a case where a semiconductor element is laminated on a substrate with an adhesive, a silver (Ag) paste having low thermal resistance is used in order to efficiently cool the semiconductor element. However, the silver paste becomes a metal body having a high elastic modulus after being cured, and there is a difference in linear expansion coefficient from the semiconductor element, so that the semiconductor element may be warped. Such warpage affects characteristics of a semiconductor device.

Therefore, in order to suppress warpage of the semiconductor element, a resin having a low elastic modulus and being curable at a low temperature is used. However, since the resin has high thermal resistance, heat generated by the semiconductor element cannot be efficiently transferred to the substrate and a heat dissipation device. For this reason, it is necessary to suppress a temperature rise of the semiconductor element by taking measures such as devising a ventilation passage, mounting a heat sink, or forcibly cooling the semiconductor element using a cooling fan.

Patent Document 1 discloses a solid-state imaging device including a package body of a hollow package and a recessed chip storage portion provided on an upper surface of the package body and formed to have a substantially stepped cross section. This chip storage portion is a chip storage portion in which semiconductor chips of different sizes can be placed on steps, and includes a connection portion electrically connected to the semiconductor chip placed on any one of the steps and a lid joined to the upper surface of the package body to seal the chip storage portion.

In this structure, in a case where the semiconductor chip is placed on an upper step of the chip storage portion, a heat conduction plate in contact with a lower surface of the semiconductor chip and a bottom surface of the chip storage portion is placed on a lower step of the chip storage portion. With this arrangement, since heat of the semiconductor chip can be transferred to the package body, the heat of the semiconductor chip can be dissipated.

Furthermore, a defective semiconductor chip having a size that can be placed on the lower step of the chip storage portion is used as the heat conduction plate. With this arrangement, since the defective semiconductor chip which is originally discarded is used, costs become low and waste can be reduced.

Patent Document 2 discloses a technique for solving a problem in which, in a solid-state imaging element, an adhesive layer interposed between imaging elements is deformed by pressing when a bonding wire is bonded to each imaging element, inclination occurs in the imaging element, whereby a distance between a lens and the imaging element varies, and light receiving sensitivity of the imaging element decreases.

Specifically, a signal processing device is fixed on a substrate, an intermediate spacer is fixed on the signal processing element, the imaging element is further fixed thereon, and thereafter, wire bonding is performed. That is, since the intermediate spacer is interposed between the signal processing element and the imaging element, it is possible to suppress occurrence of inclination in the signal processing element and the imaging element even when a pressing force is applied at the time of performing the wire bonding.

In this case, the signal processing device is fixed onto the substrate with a die bond paste. Furthermore, the intermediate spacer is fixed onto the signal processing device with a die bond paste such as a silver paste and the like. Moreover, the imaging element is fixed onto the intermediate spacer by thermal curing with a silver-free low-temperature die bond paste.

### CITATION LIST

### Patent Documents

Patent Document 1: Japanese Patent Application Laid-Open No. 2006-339291
Patent Document 2: Japanese Patent No. 3674777

### SUMMARY OF THE INVENTION

### Problems to be Solved by the Invention

However, in the solid-state imaging device described in Patent Document 1, although the heat conduction plate in contact with the lower surface of the semiconductor chip and the bottom surface of the chip storage portion is placed, it is not clear as to how the heat of the semiconductor chip is transferred from the bottom surface of the chip storage portion to the heat conduction plate.

In the solid-state imaging device described in Patent Document 2, as described in paragraph [0034] as “The intermediate spacer 21 is fixed on the signal processing element 3 using the die bond paste such as the above-described silver paste and the like.”, the signal processing element and the intermediate spacer are bonded using the silver paste. Therefore, the conventional problems cannot be fundamentally solved.

The present disclosure has been made in view of such problems, and an object of the present disclosure is to provide a semiconductor device configured to suppress a temperature rise of a semiconductor element and to suppress warpage by using a cooling medium having a low elastic modulus and high thermal conductivity, a method for manufacturing a semiconductor device including a cooling medium sealing step, and an electronic apparatus including the semiconductor device.

### Solutions to Problems

The present disclosure has been made to solve the above-described problems, and a first aspect thereof is a semiconductor device including: a semiconductor element; a substrate to which the semiconductor element is fixed; and a cooling medium with which a clearance formed when the semiconductor element and the substrate are fixed to each other is filled.

Furthermore, in this first aspect, the cooling medium may be a liquid metal.

Furthermore, in this first aspect, the cooling medium may be a metal-coated small sphere.

Furthermore, in this first aspect, the cooling medium may be a liquid metal and a metal-coated small sphere.

Furthermore, in this first aspect, the cooling medium with which the clearance is filled may be disposed below a heat generating source of the semiconductor element.

Furthermore, in this first aspect, the clearance may be formed by the substrate, the semiconductor element, and an adhesive applied to an entire peripheral edge of the semiconductor element to fix both the substrate and the semiconductor element, and an upper surface of the substrate may be covered with a low surface tension material along an inner periphery of the adhesive.

Furthermore, in this first aspect, the clearance may be formed by the substrate, the semiconductor element, and an adhesive applied to an entire peripheral edge of the semiconductor element to fix both the substrate and the semiconductor element, and a partition having a height lower than a thickness height of the adhesive may protrude from an upper surface of the substrate along an inner periphery of the adhesive.

Furthermore, in this first aspect, a heat exhausting mechanism may be provided on a lower surface of the substrate.

A second aspect of the present disclosure is a method for manufacturing a semiconductor device including: applying an adhesive in such a manner as to surround a region on a substrate where a cooling medium is disposed; injecting the cooling medium into a region surrounded by the adhesive; and adhering a semiconductor element onto the adhesive.

Furthermore, in this second aspect, the cooling medium injected into the surrounded region may be a liquid metal.

Furthermore, in this second aspect, the cooling medium injected into the surrounded region may be a metal-coated small sphere.

Furthermore, in this second aspect, the cooling medium injected into the surrounded region may be a liquid metal and a metal-coated small sphere.

A third aspect of the present disclosure is a method for manufacturing a semiconductor device including: applying an adhesive in such a manner as to surround a region on a substrate where a cooling medium is disposed; adhering a semiconductor element onto the adhesive; injecting the cooling medium into a clearance formed by the substrate, the adhesive, and the semiconductor element; and sealing the clearance.

Furthermore, in this third aspect, the cooling medium injected into the clearance may be a liquid metal.

Furthermore, in this third aspect, the cooling medium injected into the clearance may be a metal-coated small sphere.

Furthermore, in this third aspect, the cooling medium injected into the clearance may be a liquid metal and a metal-coated small sphere.

A fourth aspect of the present disclosure is a method for manufacturing a semiconductor device including: placing metal-coated small spheres on a plurality of recesses provided on a substrate; applying an adhesive in such a manner as to surround the disposed metal-coated small spheres; and adhering a semiconductor element onto the adhesive.

A fifth aspect of the present disclosure is a method for manufacturing a semiconductor device including: placing metal-coated small spheres on a plurality of soldering pads disposed on a substrate; soldering the placed metal-coated small spheres; applying an adhesive in such a manner as to surround the placed metal-coated small spheres; and adhering a semiconductor element onto the adhesive.

A sixth aspect of the present disclosure is a method for manufacturing a semiconductor device including: placing metal-coated small spheres on a plurality of soldering pads disposed on a lower surface of a semiconductor element; soldering the placed metal-coated small spheres; applying an adhesive to the substrate or the lower surface of the semiconductor element in such a manner as to surround the metal-coated small spheres when the surface of the semiconductor element to which the metal-coated small spheres are soldered is placed on the substrate; and adhering the surface of the semiconductor element to which the metal-coated small spheres are soldered onto the adhesive.

Furthermore, the fourth to sixth aspects may further include: injecting a liquid metal into a clearance formed by the substrate, the semiconductor element, and the adhesive applied in such a manner as to surround the metal-coated small spheres.

A seventh aspect of the present disclosure is an electronic apparatus having a semiconductor device including: a semiconductor element; a substrate to which the semiconductor element is fixed; and a cooling medium with which a clearance formed when the semiconductor element and the substrate are fixed to each other is filled.

According to the aspects described above, it is possible to provide a semiconductor device, a method for manufacturing a semiconductor device having a cooling medium sealing step, and an electronic apparatus having the semiconductor device.

### BRIEF DESCRIPTION OF DRAWINGS

FIG. 1 is a sectional view and a plan sectional view of a basic form of a first embodiment of a semiconductor device according to the present disclosure.

FIG. 2 is a plan sectional view of Modification 1 of the first embodiment of the semiconductor device according to the present disclosure.

FIG. 3 is a plan sectional view of Modification 2 of the first embodiment of the semiconductor device according to the present disclosure.

FIG. 4 is a plan sectional view of Modification 3 of the first embodiment of the semiconductor device according to the present disclosure.

FIG. 5 is an external perspective view of a cooling medium used in a second embodiment of a semiconductor device according to the present disclosure.

FIG. 6 is a sectional view and a plan sectional view of a basic form of the second embodiment of the semiconductor device according to the present disclosure.

FIG. 7 is a plan sectional view of Modification 1 of the second embodiment of the semiconductor device according to the present disclosure.

FIG. 8 is a plan sectional view of Modification 2 of the second embodiment of the semiconductor device according to the present disclosure.

FIG. 9 is a plan sectional view of Modification 3 of the second embodiment of the semiconductor device according to the present disclosure.

FIG. 10 is a sectional view and a plan sectional view of a basic form of a third embodiment of a semiconductor device according to the present disclosure.

FIG. 11 is a step explanatory view of a first example of a cooling medium sealing step in the first embodiment of the semiconductor device according to the present disclosure (part 1).

FIG. 12 is a step explanatory view of the first example of the cooling medium sealing step in the first embodiment of the semiconductor device according to the present disclosure (part 2).

FIG. 13 is a step explanatory view of the first example of the cooling medium sealing step in the first embodiment of the semiconductor device according to the present disclosure (part 3).

FIG. 14 is a step explanatory view of the first example of the cooling medium sealing step in the first embodiment of the semiconductor device according to the present disclosure (part 4).

FIG. 15 is a step explanatory view of a second example of a cooling medium sealing step in the first embodiment of the semiconductor device according to the present disclosure (part 1).

FIG. 16 is a step explanatory view of the second example of the cooling medium sealing step in the first embodiment of the semiconductor device according to the present disclosure (part 2).

FIG. 17 is a step explanatory view of the second example of the cooling medium sealing step in the first embodiment of the semiconductor device according to the present disclosure (part 3).

FIG. 18 is a step explanatory view of the second example of the cooling medium sealing step in the first embodiment of the semiconductor device according to the present disclosure (part 4).

FIG. 19 is a step explanatory view of the second example of the cooling medium sealing step in the first embodiment of the semiconductor device according to the present disclosure (part 5).

FIG. 20 is a step explanatory view of a first example of a cooling medium sealing step in the second embodiment of the semiconductor device according to the present disclosure (part 1).

FIG. 21 is a step explanatory view of the first example of the cooling medium sealing step in the second embodiment of the semiconductor device according to the present disclosure (part 2).

FIG. 22 is a step explanatory view of the first example of the cooling medium sealing step in the second embodiment of the semiconductor device according to the present disclosure (part 3).

FIG. 23 is a step explanatory view of the first example of the cooling medium sealing step in the second embodiment of the semiconductor device according to the present disclosure (part 4).

FIG. 24 is a step explanatory view of a second example of a cooling medium sealing step in the second embodiment of the semiconductor device according to the present disclosure (part 1).

FIG. 25 is a step explanatory view of the second example of the cooling medium sealing step in the second embodiment of the semiconductor device according to the present disclosure (part 2).

FIG. 26 is a step explanatory view of the second example of the cooling medium sealing step in the second embodiment of the semiconductor device according to the present disclosure (part 3).

FIG. 27 is a step explanatory view of the second example of the cooling medium sealing step in the second embodiment of the semiconductor device according to the present disclosure (part 4).

FIG. 28 is a step explanatory view of the second example of the cooling medium sealing step in the second embodiment of the semiconductor device according to the present disclosure (part 5).

FIG. 29 is a step explanatory view of a third example of a cooling medium sealing step in the second embodiment of the semiconductor device according to the present disclosure (part 1).

FIG. 30 is a step explanatory view of the third example of the cooling medium sealing step in the second embodiment of the semiconductor device according to the present disclosure (part 2).

FIG. 31 is a step explanatory view of the third example of the cooling medium sealing step in the second embodiment of the semiconductor device according to the present disclosure (part 3).

FIG. 32 is a step explanatory view of the third example of the cooling medium sealing step in the second embodiment of the semiconductor device according to the present disclosure (part 4).

FIG. 33 is a step explanatory view of the third example of the cooling medium sealing step in the second embodiment of the semiconductor device according to the present disclosure (part 5).

FIG. 34 is a step explanatory view of a fourth example of a cooling medium sealing step in the second embodiment of the semiconductor device according to the present disclosure (part 1).

FIG. 35 is a step explanatory view of the fourth example of the cooling medium sealing step in the second embodiment of the semiconductor device according to the present disclosure (part 2).

FIG. 36 is a step explanatory view of the fourth example of the cooling medium sealing step in the second embodiment of the semiconductor device according to the present disclosure (part 3).

FIG. 37 is a step explanatory view of the fourth example of the cooling medium sealing step in the second embodiment of the semiconductor device according to the present disclosure (part 4).

FIG. 38 is a step explanatory view of the fourth example of the cooling medium sealing step in the second embodiment of the semiconductor device according to the present disclosure (part 5).

FIG. 39 is a step explanatory view of the fourth example of the cooling medium sealing step in the second embodiment of the semiconductor device according to the present disclosure (part 6).

FIG. 40 is a step explanatory view of a fifth example of a cooling medium sealing step in the second embodiment of the semiconductor device according to the present disclosure (part 1).

FIG. 41 is a step explanatory view of the fifth example of the cooling medium sealing step in the second embodiment of the semiconductor device according to the present disclosure (part 2).

FIG. 42 is a step explanatory view of the fifth example of the cooling medium sealing step in the second embodiment of the semiconductor device according to the present disclosure (part 3).

FIG. 43 is a step explanatory view of a first example of a cooling medium sealing step in the third embodiment of the semiconductor device according to the present disclosure (part 1).

FIG. 44 is a step explanatory view of the first example of the cooling medium sealing step in the third embodiment of the semiconductor device according to the present disclosure (part 2).

FIG. 45 is a step explanatory view of the first example of the cooling medium sealing step in the third embodiment of the semiconductor device according to the present disclosure (part 3).

FIG. 46 is a step explanatory view of the first example of the cooling medium sealing step in the third embodiment of the semiconductor device according to the present disclosure (part 4).

FIG. 47 is a step explanatory view of the first example of the cooling medium sealing step in the third embodiment of the semiconductor device according to the present disclosure (part 5).

FIG. 48 is a step explanatory view of a second example of a cooling medium sealing step in the third embodiment of the semiconductor device according to the present disclosure (part 1).

FIG. 49 is a step explanatory view of the second example of the cooling medium sealing step in the third embodiment of the semiconductor device according to the present disclosure (part 2).

FIG. 50 is a step explanatory view of the second example of the cooling medium sealing step in the third embodiment of the semiconductor device according to the present disclosure (part 3).

FIG. 51 is a step explanatory view of the second example of the cooling medium sealing step in the third embodiment of the semiconductor device according to the present disclosure (part 4).

FIG. 52 is a step explanatory view of the second example of the cooling medium sealing step in the third embodiment of the semiconductor device according to the present disclosure (part 5).

FIG. 53 is a step explanatory view of the second example of the cooling medium sealing step in the third embodiment of the semiconductor device according to the present disclosure (part 6).

FIG. 54 is a sectional view of a fourth embodiment of a semiconductor device according to the present disclosure.

FIG. 55 is an explanatory view of a cooling medium sealing structure of the semiconductor device according to the present disclosure (part 1).

FIG. 56 is an explanatory view of the cooling medium sealing structure of the semiconductor device according to the present disclosure (part 2).

FIG. 57 is an explanatory view of the cooling medium sealing structure of the semiconductor device according to the present disclosure (part 3).

FIG. 58 is a block diagram of an electronic apparatus including the semiconductor device according to the present disclosure.

### MODES FOR CARRYING OUT THE INVENTION

Next, modes for carrying out the present disclosure (hereinafter, referred to as “embodiments”) will be described in the following order with reference to the drawings. In the following drawings, the same or similar parts are denoted by the same or similar reference numerals. However, the drawings are schematic, and dimensional ratios and the like of the respective parts do not necessarily match actual ones. Furthermore, it is needless to say that the drawings include parts having different dimensional relationships and ratios.
1. First Embodiment of Semiconductor Device According to the Present Disclosure
2. Second Embodiment of Semiconductor Device According to the Present Disclosure
3. Third Embodiment of Semiconductor Device According to the Present Disclosure
4. Cooling Medium Sealing Step in First Embodiment of Semiconductor Device According to the Present Disclosure
5. Cooling Medium Sealing Step in Second Embodiment of Semiconductor Device According to the Present Disclosure
6. Cooling Medium Sealing Step in Third Embodiment of Semiconductor Device According to the Present Disclosure
7. Fourth Embodiment of Semiconductor Device According to the Present Disclosure
8. Cooling Medium Sealing Structure of Semiconductor Device According to the Present Disclosure
9. Electronic Apparatus Including Semiconductor Device According to the Present disclosure

### <1. First Embodiment of Semiconductor Device According to the Present Disclosure>

### Basic Form of First Embodiment

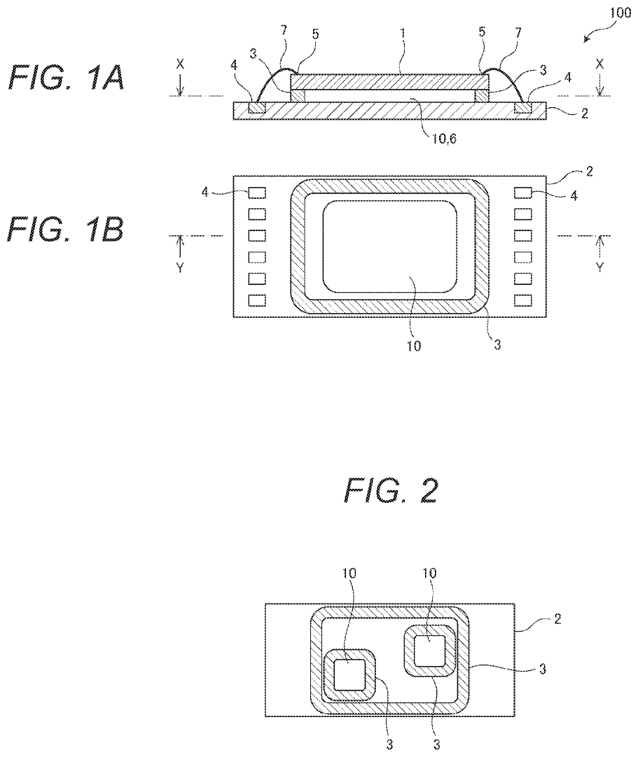

FIG. 1A is a side sectional view taken along line Y-Y of a basic form of a first embodiment of a semiconductor device 100 according to the present disclosure, and FIG. 1B is a plan sectional view taken along line X-X thereof (Hereinafter, unless otherwise specified, they are referred to as “sectional view” and “plan view”, respectively.). In the present embodiment, a liquid metal 10 is used as a cooling medium of a semiconductor element 1.

As illustrated in FIGS. 1A and 1B, the semiconductor device 100 is configured by bonding the semiconductor element 1 on a substrate 2 with an adhesive 3. That is, the adhesive 3 is applied to a peripheral edge of the semiconductor element 1 in a substantially square shape and is bonded to the substrate 2. Then, as illustrated in FIG. 1, between the substrate 2 and the semiconductor element 1, a clearance 6 formed by being surrounded by the adhesive 3 applied in the substantially square shape is filled with the liquid metal 10.

In FIGS. 1A and 1B, a solid-state imaging element such as a CMOS sensor or a CCD is described as an example of the semiconductor element 1. However, the semiconductor element 1 is not limited to the solid-state imaging element, and may be a logic, a memory, a microcomputer, or the like. Note that the solid-state imaging element will be described below as an example.

A plurality of electrode pads 5 is disposed on a peripheral edge of an upper surface of the semiconductor element 1. Furthermore, a plurality of substrate pads 4 is disposed on the substrate 2 on an outer periphery of the semiconductor element 1. This substrate pad 4 may be a pad including a copper (Cu) wiring pattern. Then, the electrode pad 5 and the substrate pad 4 are connected to each other by a bonding wire 7 such as a gold wire (Au).

Note that, in order to avoid complication, the bonding wire 7 in this drawing is described only in the sectional view of FIG. 1A, and description thereof is omitted in the plan view of FIG. 1B (The same applies hereinafter.).

In the substrate 2, the semiconductor element 1 is bonded and fixed, a wiring layer is formed, and an input/output signal of the semiconductor element 1 is connected to the outside. The substrate 2 may be a silicon (Si) substrate or an interposer substrate.

As the liquid metal 10, mercury (Hg) is widely known, and can be used as a cooling medium. However, it is desirable to use other materials from the viewpoint of environmental problems. Galinstan is known as the other liquid metal 10. Galinstan is a eutectic alloy of gallium (Ga), indium (In), and tin (Sn), and a metal composition of a liquid at normal temperature is 68.5% gallium, 21.5% indium, and 10% tin. Furthermore, it has lower toxicity than other liquid metals at another normal temperature, has a lower vapor pressure, and does not vaporize even when exposed to high heat. Furthermore, since a melting point is −19° C., a liquid state is maintained at normal temperature. Furthermore, thermal conductivity is 16.5 W/m·K, and it has a heat transfer property.

Since the present embodiment is configured as described above, adhesiveness between the semiconductor element 1 and the substrate 2 is maintained, and the liquid metal 10 disposed immediately below the semiconductor element 1 transfers heat generated by the semiconductor element 1 to the substrate 2. Therefore, a temperature rise accompanying heat generation of the semiconductor element 1 is suppressed. Furthermore, an elastic modulus is low because of being a liquid. Therefore, since the liquid metal 10 alleviates stress generated by the adhesion, warpage of the semiconductor element 1 generated in a case where conventional metal paste is used can be prevented.

The configuration and effects of the basic form of the first embodiment according to the present disclosure are as described above.

### Modification 1 of First Embodiment

FIG. 2 is a plan view of Modification 1 of the first embodiment of the semiconductor device 100 according to the present disclosure. A sectional view is substantially the same as that of FIG. 1A, and thus is omitted. Furthermore, description of the metal pad 4 is omitted except for a basic form of each embodiment in order to avoid complication (The same applies hereinafter.). In the substrate 2, as illustrated in FIG. 2, the adhesive 3 is applied in a substantially square shape to a peripheral edge of a bonding surface of the semiconductor element 1. Then, moreover, the adhesive 3 is applied to two places in a substantially small square shape in a region surrounded by the adhesive 3 applied in the substantially square shape. Then, the liquid metal 10 is sealed in a clearance 6 that is a region surrounded by the adhesive 3 applied in the substantially small square shape.

With such a configuration, in a case where a heat generating place on the bonding surface of the semiconductor element 1 is not uniform and a heat generating source exists at a specific place, the liquid metal 10 can be sealed in the clearance 6 which is the region surrounded by applying the adhesive 3 in the substantially small square shape immediately below the heat generating source, and the liquid metal 10 need not be sealed at other places. This makes it possible to save an amount of the liquid metal 10 used. Note that, in this drawing, the adhesive 3 is applied to two places in the substantially small square shape, but may be applied to three or more places.

### Modification 2 of First Embodiment

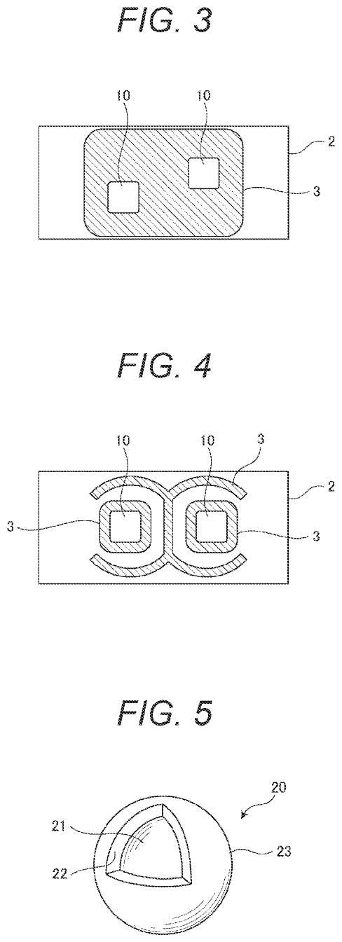

FIG. 3 is a plan view of Modification 2 of the first embodiment of the semiconductor device 100 according to the present disclosure. A sectional view is substantially the same as that of FIG. 1A, and thus is omitted. As illustrated in FIG. 3, the adhesive 3 is applied in a substantially square shape to the peripheral edge of the bonding surface of the semiconductor element 1. Then, moreover, the adhesive 3 is applied to two places in a substantially small square shape in a region surrounded by the adhesive 3 applied in the substantially square shape. Then, the liquid metal 10 is sealed in a clearance 6 that is a region surrounded by the adhesive 3 applied in the substantially small square shape. Furthermore, the adhesive 3 is applied to an entire surface of the region where the liquid metal 10 is not injected and bonded.

With such a configuration, in a case where a heat generating place on the bonding surface of the semiconductor element 1 is not uniform and a heat generating source exists at a specific place, the liquid metal 10 can be injected into the clearance 6 which is the region surrounded by applying the adhesive 3 in the substantially small square shape immediately below the heat generating source, and the adhesive 3 can be applied to the entire surface of the other places and bonded. This makes it possible to strengthen adhesion and to save an amount of the liquid metal 10 used. Note that, in this drawing, the adhesive 3 is applied to two places in the substantially small square shape, but may be applied to three or more places.

### Modification 3 of First Embodiment

FIG. 4 is a plan view of Modification 3 of the first embodiment of the semiconductor device 100 according to the present disclosure. A sectional view is substantially the same as that of FIG. 1A, and thus is omitted. As shown in FIG. 4, the adhesive 3 is applied to a lower surface of the semiconductor element 1 in a shape in which a peripheral edge portion has a substantially x shape or has a shape in which substantially C-shaped back surfaces are joined. Then, the adhesive 3 is applied in a substantially small square shape in regions surrounded by left and right arcs of the adhesive 3 applied in the substantially x shape or the shape in which the substantially C-shaped back surfaces are joined. Then, the liquid metal 10 is sealed in a clearance 6 that is a region coated and surrounded in the substantially small square shape. Furthermore, a region where the adhesive 3 is not applied in a substantially square shape is bonded so that outside air can enter and exit.

With such a configuration, in a case where a heat generating place on the bonding surface of the semiconductor element 1 is not uniform and a heat generating source exists at a specific place, the liquid metal 10 can be injected into the clearance 6 which is the region surrounded by applying the adhesive 3 in the substantially small square shape immediately below the heat generating source, and the other places can be bonded so that the outside air can enter and exit. Therefore, the outside air can flow into the clearance 6 between the bonding surfaces of the semiconductor element 1 and the substrate 2, so that a heat dissipation effect by convection can be expected. In addition, an amount of the liquid metal 10 used can be saved. Note that, in this drawing, the adhesive 3 is applied to two places in the substantially small square shape, but may be applied to three or more places.

### <2. Second Embodiment of Semiconductor Device According to the Present Disclosure>

### Basic Form of Second Embodiment

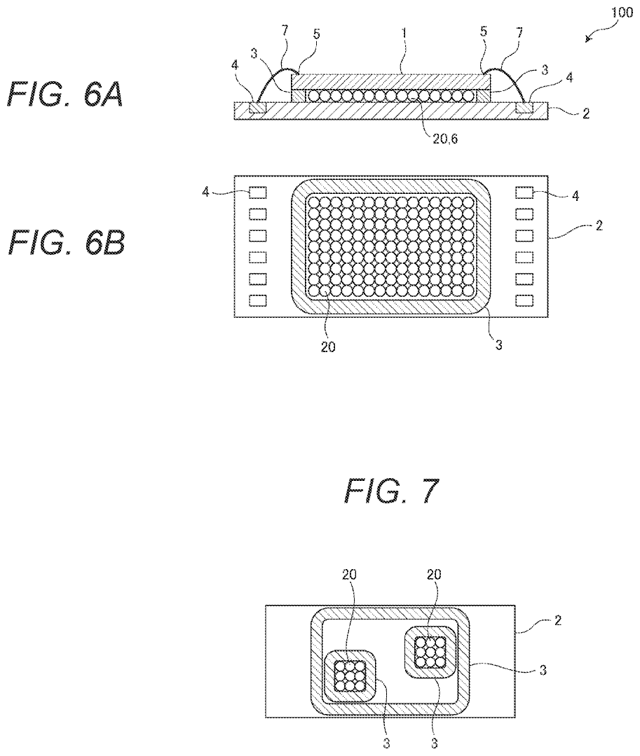

FIG. 6 is a sectional view and a plan view of a basic form of a second embodiment of a semiconductor device 100 according to the present disclosure. In the present embodiment, a metal-coated small sphere 20 is used as a cooling medium of a semiconductor element 1.

As illustrated in FIG. 6, the semiconductor device 100 is configured by bonding the semiconductor element 1 on a substrate 2 with an adhesive 3. That is, the adhesive 3 is applied to a peripheral edge of the semiconductor element 1 in a substantially square shape and is bonded to the substrate 2. Then, as illustrated in FIG. 6, between the substrate 2 and the semiconductor element 1, a large number of metal-coated small spheres 20 are sealed in a clearance 6 formed by being surrounded by the adhesive 3 applied in the substantially square shape.

In FIG. 6, similarly to the first embodiment, a solid-state imaging element such as a CMOS sensor or a CCD is described as an example of the semiconductor element 1. However, the semiconductor element 1 is not limited to the solid-state imaging element, and may be a logic, a memory, a microcomputer, or the like.

Hereinafter, the semiconductor element 1 will be described using the solid-state imaging element as an example. However, since a basic configuration of the semiconductor element 1 is similar to that of the first embodiment, description thereof will be omitted, and differences will be described.

As shown in FIG. 5, the metal-coated small sphere 20 is a monodisperse particle formed in a small spherical shape and having a particle diameter of 10 to 800 μm. A core 21 of the metal-coated small sphere 20 is a portion serving as a core, and includes a small spherical silicone rubber. A surface of the core 21 is covered with a polyimide film 22 to form a shell. Moreover, a surface of the polyimide film 22 is covered with a metal film 23 having electrical conductivity and thermal conductivity. The metal film 23 includes metal such as copper (Cu), tin (Sn), silver (Ag), or gold (Au), and is excellent in electrical conductivity and thermal conductivity. Since the metal-coated small sphere 20 is configured as described above, it has elasticity, and is deformed into a substantially flat shape when receiving an external force.

Since the present embodiment is configured as described above, adhesiveness between the semiconductor element 1 and the substrate 2 is maintained, and the metal-coated small spheres 20 disposed immediately below the semiconductor element 1 transmit heat generated by the semiconductor element 1 to the substrate 2, thereby suppressing a temperature rise of the semiconductor element 1. Furthermore, since the metal-coated small spheres 20 are deformed when receiving an external force, the metal-coated small spheres 20 are deformed to relax stress generated by adhesion. Therefore, warpage of the semiconductor element 1 generated in a case where conventional metal paste is used can be prevented. Furthermore, there is no problem even if an interval between the semiconductor element 1 and the substrate 2 is not uniformly formed.

The configuration and effects of the basic form of the second embodiment according to the present disclosure are as described above.

### Modification 1 of Second Embodiment

FIG. 7 is a plan view of Modification 1 of the second embodiment of the semiconductor device 100 according to the present disclosure. A sectional view is substantially the same as that of FIG. 6A, and thus is omitted. In the substrate 2, as illustrated in FIG. 7, the adhesive 3 is applied in a substantially square shape to a peripheral edge of a bonding surface of the semiconductor element 1. Then, moreover, the adhesive 3 is applied to two places in a substantially small square shape in a region surrounded by the adhesive 3 applied in the substantially square shape. Then, the metal-coated small spheres 20 are sealed in a clearance 6 that is a region surrounded by the adhesive 3 applied in the substantially small square shape.

Note that an effect of Modification 1 of the second embodiment is similar to that of Modification 1 of the first embodiment, and thus description thereof will be omitted.

### Modification 2 of Second Embodiment

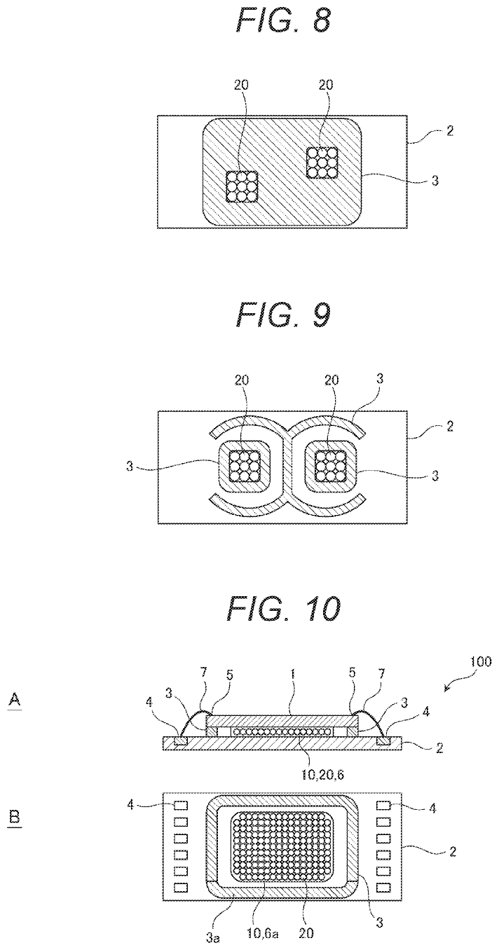

FIG. 8 is a plan view of Modification 2 of the second embodiment of the semiconductor device 100 according to the present disclosure. A sectional view is substantially the same as that of FIG. 6A, and thus is omitted. As illustrated in FIG. 8, the adhesive 3 is applied in a substantially square shape to the peripheral edge of the bonding surface of the semiconductor element 1. Then, moreover, the adhesive 3 is applied to two places in a substantially small square shape in a region surrounded by the adhesive 3 applied in the substantially square shape. Then, the metal-coated small spheres 20 are sealed in a clearance 6 that is a region surrounded by the adhesive 3 applied in the substantially small square shape. Furthermore, the adhesive 3 is applied to an entire surface of the region where the metal-coated small spheres 20 are not injected and bonded.

Note that an effect of Modification 2 of the second embodiment is similar to that of Modification 2 of the first embodiment, and thus description thereof will be omitted.

### Modification 3 of Second Embodiment

FIG. 9 is a plan view of Modification 3 of the second embodiment of the semiconductor device 100 according to the present disclosure. A sectional view is substantially the same as that of FIG. 6A, and thus is omitted. As shown in FIG. 9, the adhesive 3 is applied to a lower surface of the semiconductor element 1 in a shape in which a peripheral edge portion has a substantially x shape or has a shape in which substantially C-shaped back surfaces are joined. Then, the adhesive 3 is applied in a substantially small square shape in regions surrounded by left and right arcs of the adhesive 3 applied in the substantially x shape or the shape in which the substantially C-shaped back surfaces are joined. Then, the metal-coated small spheres 20 are sealed in a clearance 6 that is a region coated and surrounded in the substantially small square shape. Furthermore, a region where the adhesive 3 is not applied in a substantially square shape is bonded so that outside air can enter and exit.

Note that an effect of Modification 3 of the second embodiment is similar to that of Modification 3 of the first embodiment, and thus description thereof will be omitted.

### <3. Third Embodiment of Semiconductor Device According to the Present Disclosure>

### Basic Form of Third Embodiment

FIG. 10 is a sectional view and a plan view of a basic form of a third embodiment of a semiconductor device 100 according to the present disclosure. In the present embodiment, both a liquid metal 10 and a metal-coated small sphere 20 are used as a cooling medium of a semiconductor element 1.

As illustrated in FIG. 10, the semiconductor device 100 is configured by bonding the semiconductor element 1 on a substrate 2 with an adhesive 3. That is, the adhesive 3 is applied to a peripheral edge of the semiconductor element 1 in a substantially square shape and is bonded to the substrate 2. Then, as illustrated in FIG. 10, between the substrate 2 and the semiconductor element 1, a large number of metal-coated small spheres 20 are sealed in a clearance 6 formed by being surrounded by the adhesive 3 applied in the substantially square shape, and a gap 6a between the metal-coated small spheres 20 is filled with the liquid metal 10.

A basic configuration of the semiconductor element 1 and the liquid metal 10 other than those described above are similar to those in the first embodiment, and the metal-coated small spheres 20 are similar to those in the second embodiment, and thus description thereof is omitted.

Since the present embodiment is configured as described above, adhesiveness between the semiconductor element 1 and the substrate 2 is maintained, and the metal-coated small spheres 20 disposed immediately below the semiconductor element 1 transfer heat generated by the semiconductor element 1 to the substrate 2. Similarly, the liquid metal 10 with which the gap 6a between the metal-coated small spheres 20 is filled transfers the heat generated by the semiconductor element 1 to the substrate 2. Therefore, a temperature rise accompanying heat generation of the semiconductor element 1 is suppressed. Furthermore, since the liquid metal 10 and the metal-coated small spheres 20 alleviate stress generated by the adhesion, warpage of the semiconductor element 1 generated in a case where conventional metal paste is used can be prevented.

A configuration and effects of the basic form of the third embodiment according to the present disclosure are as described above.

### Modification 1 of Third Embodiment

Modification 1 of the third embodiment of the semiconductor device 100 according to the present disclosure is equivalent to that in which the gap 6a between the metal-coated small spheres 20 is filled with the liquid metal 10 in the plan view of Modification 1 of the second embodiment illustrated in FIG. 7. Furthermore, a sectional view is substantially the same as that of FIG. 6A, and thus is omitted.

Furthermore, an effect of Modification 1 of the third embodiment is similar to that obtained by adding an effect of the liquid metal 10 to the effect of Modification 1 of the second embodiment, and thus description thereof will be omitted.

### Modification 2 of Third Embodiment

Modification 2 of the third embodiment of the semiconductor device 100 according to the present disclosure is equivalent to that in which the gap 6a between the metal-coated small spheres 20 is filled with the liquid metal 10 in the plan view of Modification 2 of the second embodiment illustrated in FIG. 8. Furthermore, a sectional view is substantially the same as that of FIG. 6A, and thus is omitted.

Furthermore, an effect of Modification 2 of the third embodiment is similar to that obtained by adding the effect of the liquid metal 10 to the effect of Modification 2 of the second embodiment, and thus description thereof will be omitted.

### Modification 3 of Third Embodiment

Modification 3 of the third embodiment of the semiconductor device 100 according to the present disclosure is equivalent to that in which the gap 6a between the metal-coated small spheres 20 is filled with the liquid metal 10 in the plan view of Modification 3 of the second embodiment illustrated in FIG. 9. Furthermore, a sectional view is substantially the same as that of FIG. 6A, and thus is omitted.

Furthermore, an effect of Modification 3 of the third embodiment is similar to that obtained by adding the effect of the liquid metal 10 to the effect of Modification 3 of the second embodiment, and thus description thereof will be omitted.

### <4. Cooling Medium Sealing Step in First Embodiment of Semiconductor Device According to the Present Disclosure>

### [First Example of Cooling Medium Sealing Step in First Embodiment]

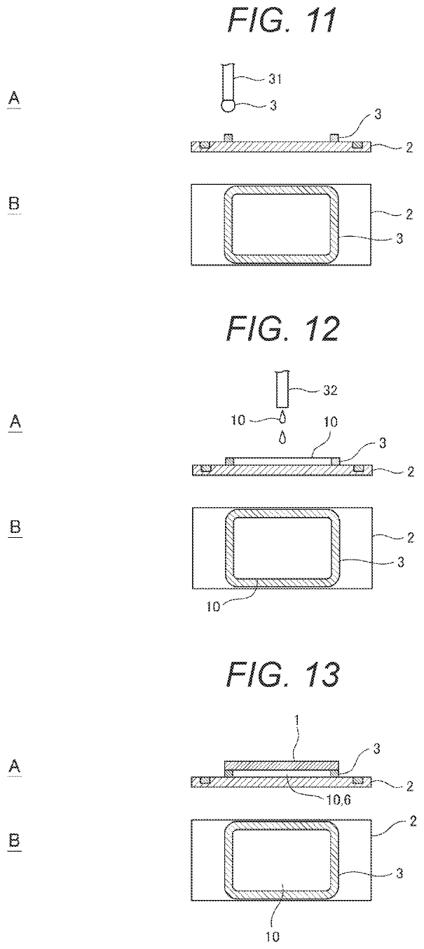

Next, a description will be given of a first example of a cooling medium sealing step in the first embodiment of the semiconductor device 100 according to the present disclosure. FIGS. 11 to 14 are step explanatory views of the first example of the step of sealing the liquid metal 10 as the cooling medium in the present embodiment. Note that the first example of the sealing step is common to the basic form and Modifications 1 to 3 of the first embodiment of the semiconductor device 100 described above. The same applies to each example of the following cooling medium sealing step.

First, as illustrated in FIG. 11, the adhesive 3 is applied in a substantially square shape along a peripheral edge of an upper surface of the substrate 2 using an adhesive application device 31.

Next, as illustrated in FIG. 12, the liquid metal 10 is injected into a substantially square region formed by applying the adhesive 3 on the substrate 2 using a liquid metal injection device 32.

Next, as illustrated in FIG. 13, the semiconductor element 1 is placed on and adhered to an upper surface of the applied adhesive 3.

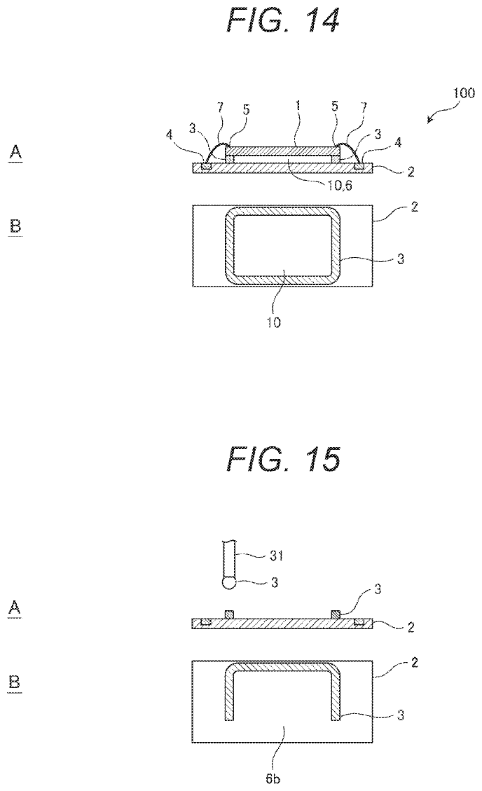

Next, as illustrated in FIG. 14, the electrode pad 5 formed on the semiconductor element 1 and the substrate pad 4 formed on the substrate 2 are connected to each other by the bonding wire 7 such as a gold wire (Au). This completes sealing of the liquid metal 10 and assembly of the semiconductor device 100.

Through the above steps, the liquid metal 10 can be sealed in the clearance 6 between the semiconductor element 1 and the substrate 2 of the semiconductor device 100 to form a thermal conductor. As a result, heat generated by the semiconductor element 1 can be transferred to the substrate 2 to suppress a temperature rise of the semiconductor element 1.

### [Second Example of Cooling Medium Sealing Step in First Embodiment]

Next, description will be given of a second example of a cooling medium sealing step in the first embodiment of the semiconductor device 100 according to the present disclosure. FIGS. 15 to 19 are step explanatory views of the second example of the cooling medium sealing step in the present embodiment.

First, as illustrated in FIG. 15, the adhesive 3 is applied in a substantially C shape or a substantially U shape along the peripheral edge of the upper surface of the substrate 2 using the adhesive application device 31. That is, it is assumed that the adhesive 3 is not applied to one long side of the semiconductor element 1 as illustrated in this drawing.

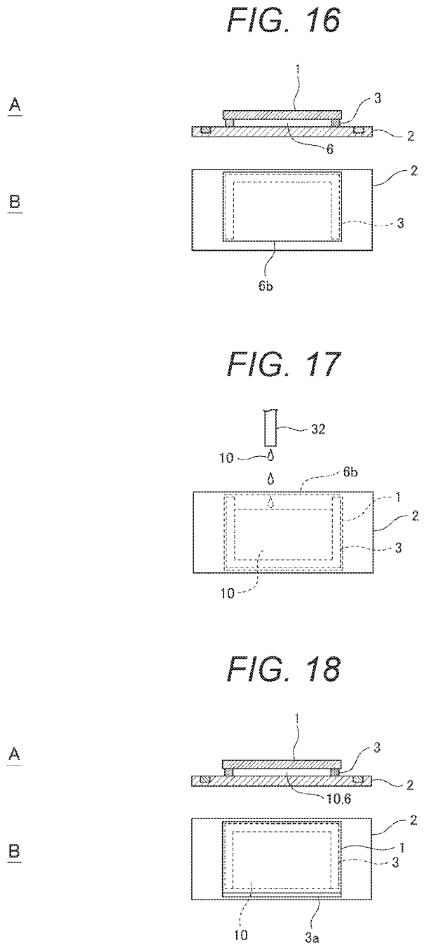

Next, as illustrated in a sectional view and a plan view of an external appearance of the semiconductor element 1 and the substrate 2 of FIG. 16, the semiconductor element 1 is placed on and adhered to an upper surface of the adhesive 3. With such adhesion, as illustrated in FIG. 16, three sides to which the adhesive 3 is applied in the substantially U shape are closed by the semiconductor element 1 and the substrate 2, and an opening 6b of the clearance 6 is formed on the long side of the semiconductor element 1 to which the adhesive 3 is not applied. Note that, in the plan view of the external appearance, description of a cover glass and the like disposed on the upper surface of the semiconductor element 1 which is a solid-state imaging element is omitted. Hereinafter, the same applies to a front view.

Next, as illustrated in FIG. 17, the semiconductor element 1 and the substrate 2 integrated by adhesion are inclined such that the opening 6b of the clearance 6 opened on the long side of the semiconductor element 1 faces upward. Then, the liquid metal 10 is injected into the clearance 6 between the semiconductor element 1 and the substrate 2 through the opening 6b of the clearance 6 using the liquid metal injection device 32. Note that an angle of inclination is usually 90°, but is not limited thereto, and is only required to be determined according to ease of injection work. For example, it may be 60°. The same applies hereinafter.

Next, a sealing adhesive 3a is applied to the opening 6b of the clearance 6. Therefore, as illustrated in a sectional view and a plan view of an external appearance in FIG. 18, the liquid metal 10 is sealed in the substantially square clearance 6 formed between the substrate 2 and the semiconductor element 1.

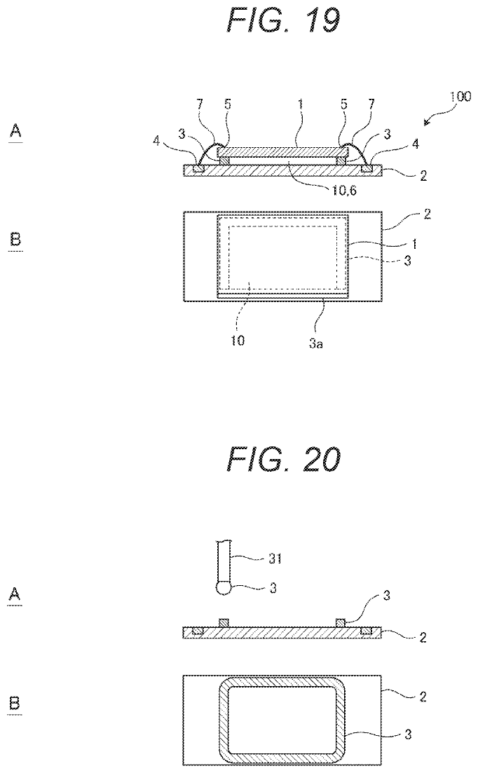

Next, in FIG. 19, in a manner similar to that described with reference to FIG. 14, sealing of the metal-coated small spheres 20 and assembly of the semiconductor device 100 are completed by performing connection by the bonding wire 7.

Through the above steps, the liquid metal 10 can be sealed in the clearance 6 between the semiconductor element 1 and the substrate 2 of the semiconductor device 100 to form a thermal conductor. As a result, heat generated by the semiconductor element 1 can be transferred to the substrate 2 to suppress a temperature rise of the semiconductor element 1.

Moreover, warpage of the semiconductor element 1 generated in a case where conventional metal paste is used can be prevented from occurring.

Furthermore, since the liquid metal 10 is injected through the opening 6b by inclining the substrate 2 and the semiconductor element 1 integrated by adhesion, the liquid metal 10 is hardly spilled, and furthermore, it is easy to confirm that the injection is performed in an appropriate amount. Moreover, sealing can be performed by applying the sealing adhesive 3a to the opening 6b, sealing is easy.

Note that, in the second example, an example in which the opening 6b of the clearance 6 is disposed on the entire long side of the semiconductor element 1 has been described, but the opening 6b does not need to be largely opened as illustrated in this drawing. For example, the opening 6b may open a small hole, an injection port of the liquid metal injection device 32 may be formed to be thin in a needle shape of a syringe and inserted into the opening 6b, and then the liquid metal 10 may be injected. Then, when the injection is completed, the small hole of the opening 6b is only required to be sealed with the sealing adhesive 3a.

With such a configuration, the liquid metal 10 can be easily handled, and sealing with the sealing adhesive 3a can be performed more easily.

### <5. Cooling Medium Sealing Step in Second Embodiment of Semiconductor Device According to the Present Disclosure>

### [First Example of Cooling Medium Sealing Step in Second Embodiment]

Next, description will be given of a first example of a cooling medium sealing step in the second embodiment of the semiconductor device 100 according to the present disclosure. FIGS. 20 to 23 are step explanatory views of the first example of the step of sealing the metal-coated small spheres 20 as the cooling medium in the present embodiment.

First, as illustrated in FIG. 20, the adhesive 3 is applied in a substantially square shape along the peripheral edge of the upper surface of the substrate 2 using the adhesive application device 31.

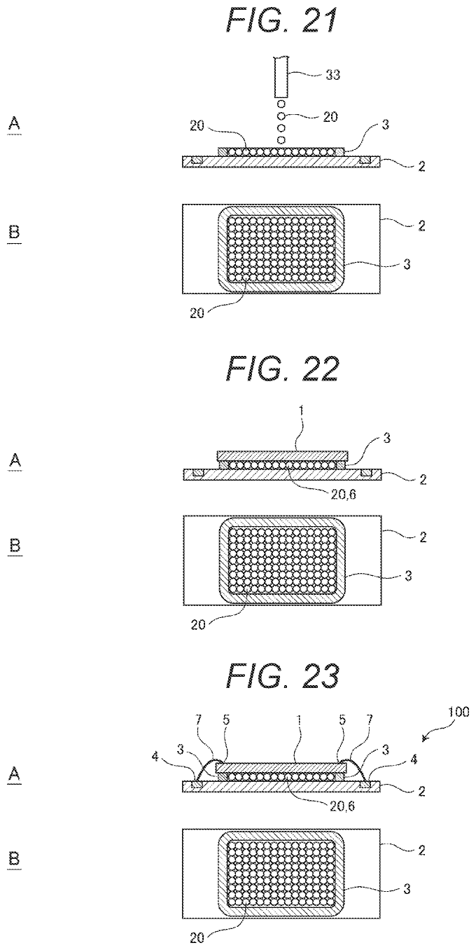

Next, as illustrated in FIG. 21, the metal-coated small spheres 20 are injected into a substantially square region formed by applying the adhesive 3 on the substrate 2 using a small sphere injection device 33.

Next, as illustrated in FIG. 22, the semiconductor element 1 is placed on and adhered to an upper surface of the applied adhesive 3.

Next, in FIG. 23, in a manner similar to that described with reference to FIG. 14, sealing of the metal-coated small spheres 20 and assembly of the semiconductor device 100 are completed by performing connection by the bonding wire 7.

Through the above steps, the metal-coated small spheres 20 can be sealed in the clearance 6 between the semiconductor element 1 and the substrate 2 of the semiconductor device 100 to form a thermal conductor. As a result, heat generated by the semiconductor element 1 can be transferred to the substrate 2 to suppress a temperature rise of the semiconductor element 1.

### [Second Example of Cooling Medium Sealing Step in Second Embodiment]

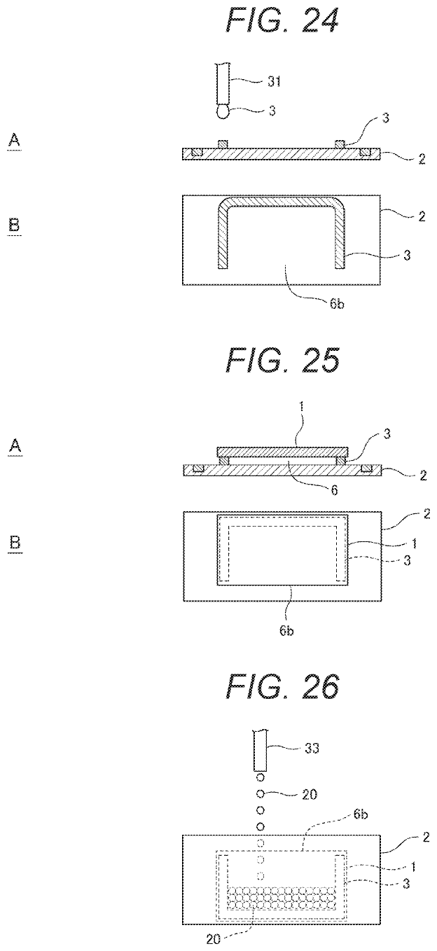

Next, description will be given of a second example of a cooling medium sealing step in the second embodiment of the semiconductor device 100 according to the present disclosure. FIGS. 24 to 28 are step explanatory views of the second example of the cooling medium sealing step in the present embodiment.

First, as illustrated in FIG. 24, the adhesive 3 is applied in a substantially C shape or a substantially U shape along the peripheral edge of the upper surface of the substrate 2 using the adhesive application device 31. That is, it is assumed that the adhesive 3 is not applied to one long side of the semiconductor element 1 as illustrated in this drawing.

Next, as illustrated in FIG. 25, the semiconductor element 1 is placed on and adhered to an upper surface of the applied adhesive 3. With such adhesion, as illustrated in FIG. 25, three sides to which the adhesive 3 is applied in the substantially U shape are closed by the semiconductor element 1 and the substrate 2, and an opening 6b of the clearance 6 is formed on the long side of the semiconductor element 1 to which the adhesive 3 is not applied.

Next, as illustrated in FIG. 26, the semiconductor element 1 and the substrate 2 integrated by adhesion are inclined such that the opening 6b of the clearance 6 opened on the long side of the semiconductor element 1 faces upward, similarly to the description with reference to FIG. 17. Then, the metal-coated small spheres 20 are injected into the clearance 6 between the semiconductor element 1 and the substrate 2 through the opening 6b of the clearance 6 using the small sphere injection device 33.

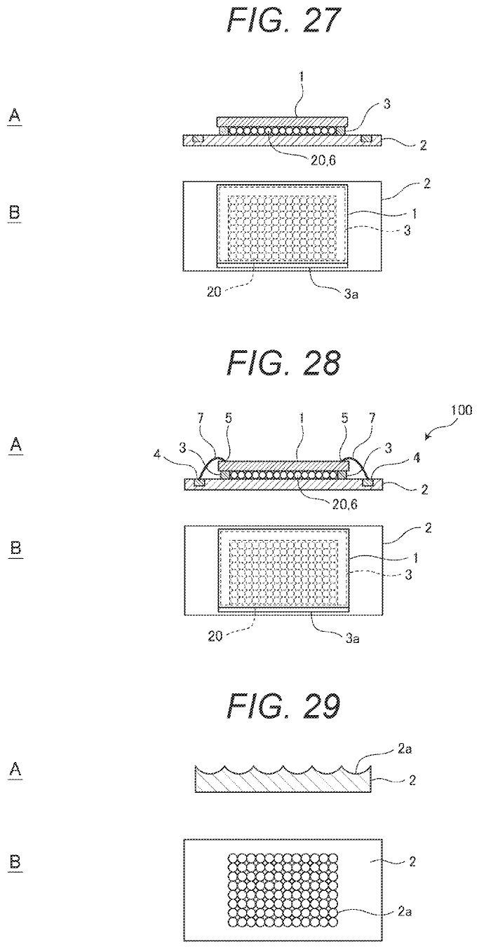

Next, a sealing adhesive 3a is applied to the opening 6b of the clearance 6. Therefore, as illustrated in a sectional view and a plan view of an external appearance in FIG. 27, the metal-coated small spheres 20 are sealed in the substantially square clearance 6 formed between the substrate 2 and the semiconductor element 1.

Next, in FIG. 28, in a manner similar to that described with reference to FIG. 14, sealing of the metal-coated small spheres 20 and assembly of the semiconductor device 100 are completed by performing connection by the bonding wire 7.

Through the above steps, the metal-coated small spheres 20 can be sealed in the clearance 6 between the semiconductor element 1 and the substrate 2 of the semiconductor device 100 to form a thermal conductor. As a result, heat generated by the semiconductor element 1 can be transferred to the substrate 2 to suppress a temperature rise of the semiconductor element 1. Furthermore, other effects are similar to a case in the second example of the cooling medium sealing step in the first embodiment, and thus description thereof is omitted.

### [Third Example of Cooling Medium Sealing Step in Second Embodiment]

Next, description will be given of a third example of a cooling medium sealing step in the second embodiment of the semiconductor device 100 according to the present disclosure. In the third example, a substantially hemispherical recess 2a is preliminarily provided at an arrangement position of the metal-coated small sphere 20 on the substrate 2 to be fixed. FIGS. 29 to 33 are step explanatory views of the third example of the cooling medium sealing step in the present embodiment. Note that sectional views of FIGS. 29 to 32 are enlarged views of a portion of the substrate 2 where the metal-coated small spheres 20 are disposed.

First, as illustrated in FIG. 29, a predetermined number of substantially hemispherical recesses 2a are provided on the upper surface of the substrate 2 in order to preliminarily fix positions where the metal-coated small spheres 20 are disposed on the substrate 2.

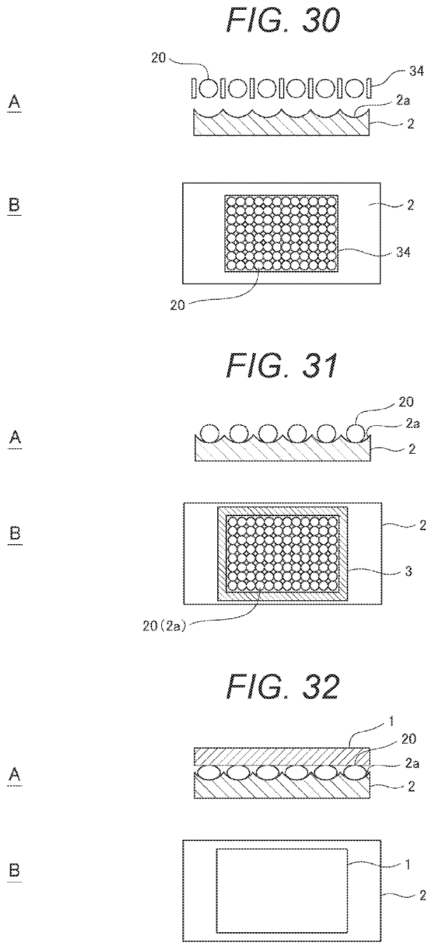

Next, as illustrated in FIG. 30, a predetermined number of metal-coated small spheres 20 are gripped by a small sphere placing jig 34 and arranged on the substantially hemispherical recesses 2a provided on the upper surface of the substrate 2.

Next, as illustrated in FIG. 31, the small sphere placing jig 34 releases the predetermined number of gripped metal-coated small spheres 20 and places them on the substantially hemispherical recesses 2a provided on the upper surface of the substrate 2. Then, the adhesive 3 is applied in a substantially square shape along a peripheral edge of the metal-coated small spheres 20 placed on the upper surface of the substrate 2 using the adhesive application device 31.

Next, as illustrated in a sectional view and a plan view of an external appearance of FIG. 32, the semiconductor element 1 is placed on and adhered to an upper surface of the applied adhesive 3.

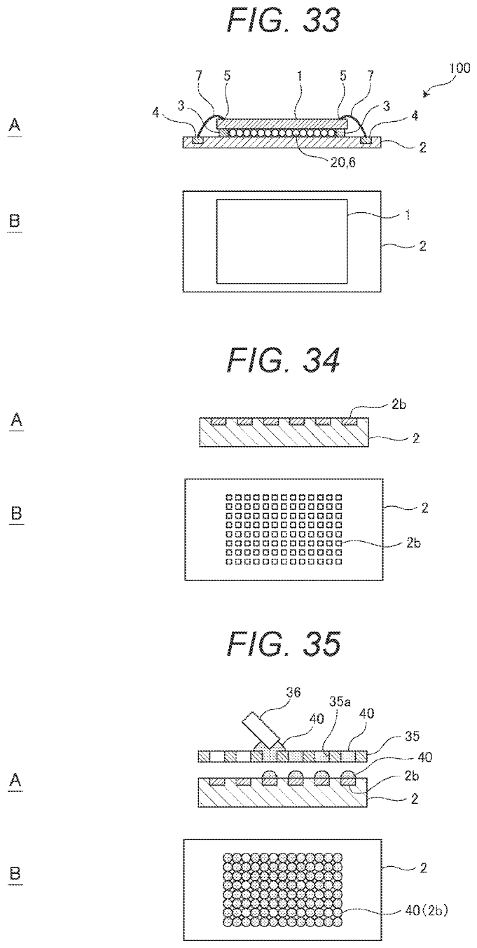

Next, in FIG. 33, in a manner similar to that described with reference to FIG. 14, sealing of the metal-coated small spheres 20 and assembly of the semiconductor device 100 are completed by performing connection by the bonding wire 7. Note that, in the present embodiment, an example in which the metal-coated small spheres 20 are placed on the substantially hemispherical recesses 2a provided on the upper surface of the substrate 2 has been described, but the metal-coated small spheres 20 may be adhered onto the recesses 2a.

Through the above steps, the metal-coated small spheres 20 can be sealed in the clearance 6 between the semiconductor element 1 and the substrate 2 of the semiconductor device 100 to form a thermal conductor. As a result, heat generated by the semiconductor element 1 can be transferred to the substrate 2 to suppress a temperature rise of the semiconductor element 1.

Furthermore, by adhering the metal-coated small spheres 20 to the substrate 2 in advance as in the present example, it is possible to reliably arrange a required number of metal-coated small spheres 20 immediately below the vicinity of a heat generating source. Therefore, it is possible to control an effect of suppressing the temperature rise, and it is possible to obtain an optimum effect with a minimum required number without causing variation.

### [Fourth Example of Cooling Medium Sealing Step in Second Embodiment]

Next, description will be given of a fourth example of a cooling medium sealing step in the second embodiment of the semiconductor device 100 according to the present disclosure. In the fourth example, a soldering pad 2b is disposed in advance at an arrangement position of the metal-coated small sphere 20 on the substrate 2 and fixed by soldering. FIGS. 34 to 39 are step explanatory views of the fourth example of the cooling medium sealing step in the present embodiment. Note that sectional views of FIGS. 34 to 38 are enlarged views of a portion of the substrate 2 where the metal-coated small spheres 20 are disposed.

First, as illustrated in FIG. 34, a predetermined number of soldering pads 2b are formed on the upper surface of the substrate 2 in order to preliminarily fix positions where the metal-coated small spheres 20 are disposed on the substrate 2.

Next, as illustrated in FIG. 35, a metal mask 35 for applying cream solder (also referred to as “solder paste”) 40 to the soldering pad 2b is closely fixed to the upper surface of the substrate 2 in accordance with the arrangement of the soldering pads 2b. Then, the cream solder 40 is applied to the soldering pads 2b via the metal mask 35 using a squeegee 36.

Specifically, the metal mask 35 is a mask (jig) for applying cream solder to a position of the soldering pad 2b used when soldering by reflow is performed. In the metal mask 35, a mask hole 35a matching the position and shape of the soldering pad 2b is drilled in a metal thin plate. Then, by applying the cream solder 40 to the metal mask 35 using a brush called the squeegee 36, the cream solder 40 having passed through the mask hole 35a is applied to the soldering pad 2b of the substrate 2.

Note that this drawing illustrates a state in which the metal mask 35 is lifted in the middle of applying the cream solder 40 for convenience of description.

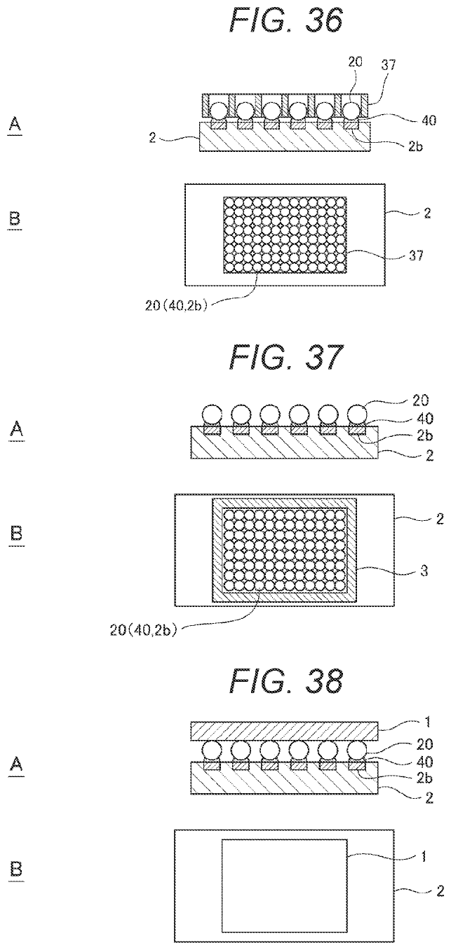

Next, as shown in FIG. 36, a predetermined number of metal-coated small spheres 20 are gripped by a soldering jig 37 and arranged on the soldering pads 2b of the substrate 2 to which the cream solder 40 is applied.

Next, the soldering jig 37 releases the predetermined number of gripped metal-coated small spheres 20 and places them on the cream solder 40 applied to the upper surface of the substrate 2, as illustrated in FIG. 37. Then, the metal-coated small spheres 20 are soldered to the soldering pads 2b by passing through a reflow furnace (not illustrated). Note that the soldering jig 37 may be passed through the reflow furnace in a detached state. Alternatively, it may be passed through the reflow furnace in an attached state.

When the soldering is completed and the substrate 2 is cooled to normal temperature, the adhesive 3 is applied in a substantially square shape along a peripheral edge of the metal-coated small spheres 20 placed on the upper surface of the substrate 2 using the adhesive application device 31.

Next, as illustrated in a sectional view and a plan view of an external appearance of FIG. 38, the semiconductor element 1 is placed on and adhered to an upper surface of the applied adhesive 3.

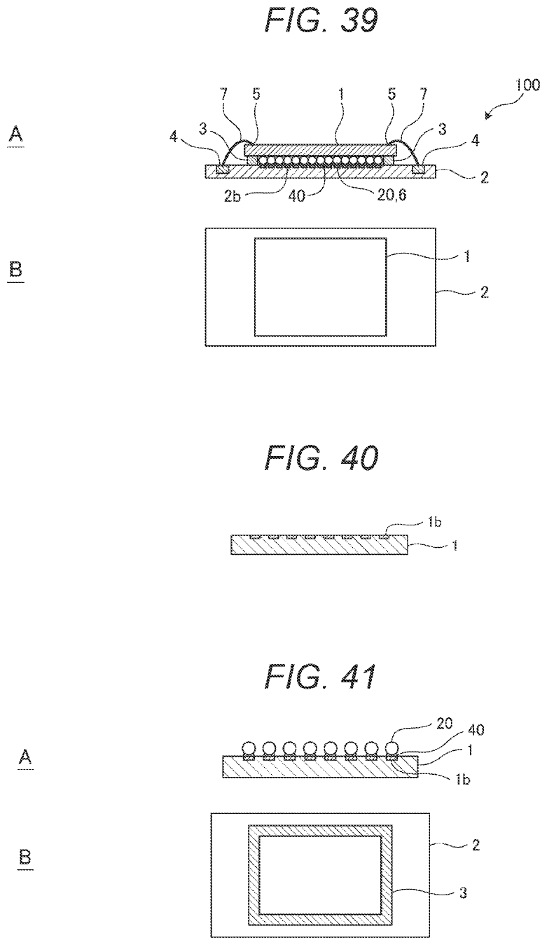

Next, in FIG. 39, in a manner similar to that described with reference to FIG. 14, sealing of the metal-coated small spheres 20 and assembly of the semiconductor device 100 are completed by performing connection by the bonding wire 7.

Through the above steps, the metal-coated small spheres 20 can be sealed in the clearance 6 between the semiconductor element 1 and the substrate 2 of the semiconductor device 100 to form a thermal conductor. As a result, heat generated by the semiconductor element 1 can be transferred to the substrate 2 to suppress a temperature rise of the semiconductor element 1. Furthermore, other effects are similar to a case in the third example of the cooling medium sealing step in the second embodiment, and thus description thereof is omitted.

### [Fifth Example of Cooling Medium Sealing Step in Second Embodiment]

Next, description will be given of a fifth example of a cooling medium sealing step in the second embodiment of the semiconductor device 100 according to the present disclosure. In the fifth example, a soldering pad 1b is formed not on the substrate 2 side but on a lower surface on the semiconductor element 1 side, and the metal-coated small sphere 20 is soldered thereto to be fixed. FIGS. 40 to 42 are step explanatory views of the fifth example of the cooling medium sealing step in the present embodiment. Note that sectional views of FIGS. 40 to 42 are enlarged views of a portion of the semiconductor element 1 where the metal-coated small spheres 20 are disposed.

First, as illustrated in FIG. 40, a predetermined number of soldering pads 1b are formed on the lower surface of the semiconductor element 1 in order to preliminarily fix positions where the metal-coated small spheres 20 are disposed on the lower surface of the semiconductor element 1. Note that, in this drawing, since the semiconductor element 1 is turned upside down in order to apply the cream solder 40, the lower surface faces upward.

Next, the cream solder 40 is applied to the soldering pads 1b using the metal mask 35. Here, since an application method of the cream solder 40 is similar to that described in FIG. 35, description thereof is omitted.

Next, in a manner similar to that described with reference to FIG. 36, a predetermined number of metal-coated small spheres 20 are gripped by the soldering jig 37 and placed on the cream solder 40 applied to the soldering pads 1b of the semiconductor element 1, as illustrated in FIG. 41.

Next, the semiconductor element 1 on which the metal-coated small spheres 20 are placed is passed through the reflow furnace (not illustrated) to solder the metal-coated small spheres 20 to the soldering pads 1b. After the soldering is finished, the semiconductor element 1 is cooled to room temperature. The step of soldering by reflow is similar to that described in FIGS. 36 and 37.

Furthermore, in parallel with this, when the lower surface of the semiconductor element 1, to which the metal-coated small spheres 20 are soldered, is placed on the substrate 2, the adhesive 3 is applied onto the substrate 2 in a substantially square shape using the adhesive application device 31 so as to be able to adhere in a manner of surrounding the metal-coated small spheres 20.

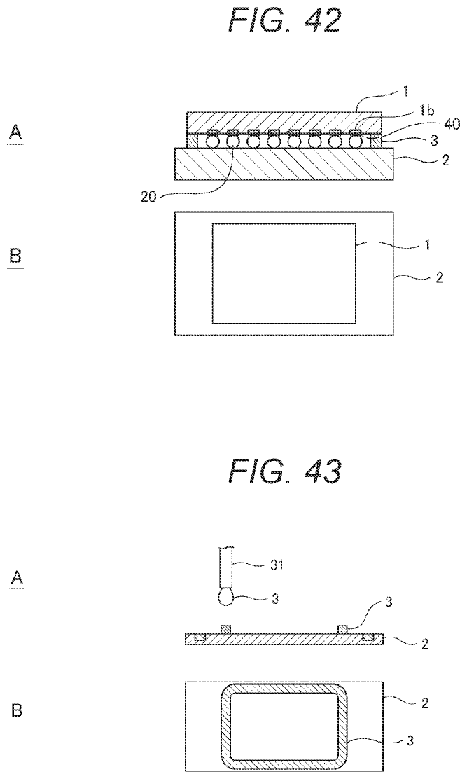

Next, as illustrated in FIG. 42, the semiconductor element 1 is placed on and adhered to an upper surface of the applied adhesive 3.

Next, in a manner similar to that described with reference to FIG. 14, sealing of the metal-coated small spheres 20 and assembly of the semiconductor device 100 are completed by performing connection by the bonding wire 7.

Through the above steps, the metal-coated small spheres 20 can be sealed in the clearance 6 between the semiconductor element 1 and the substrate 2 of the semiconductor device 100 to form a thermal conductor. As a result, heat generated by the semiconductor element 1 can be transferred to the substrate 2 to suppress a temperature rise of the semiconductor element 1. Furthermore, other effects are similar to a case in the third example of the cooling medium sealing step in the second embodiment, and thus description thereof is omitted.

### <6. Cooling Medium Sealing Step in Third Embodiment of Semiconductor Device According to the Present Disclosure>

### [First Example of Cooling Medium Sealing Step in Third Embodiment]

Next, description will be given of a first example of a cooling medium sealing step in the third embodiment of the semiconductor device 100 according to the present disclosure. FIGS. 43 to 47 are step explanatory views of the first example of the step of sealing the liquid metal 10 and the metal-coated small spheres 20 as the cooling medium in the present embodiment.

First, as illustrated in FIG. 43, the adhesive 3 is applied in a substantially square shape along the peripheral edge of the upper surface of the substrate 2 using the adhesive application device 31.

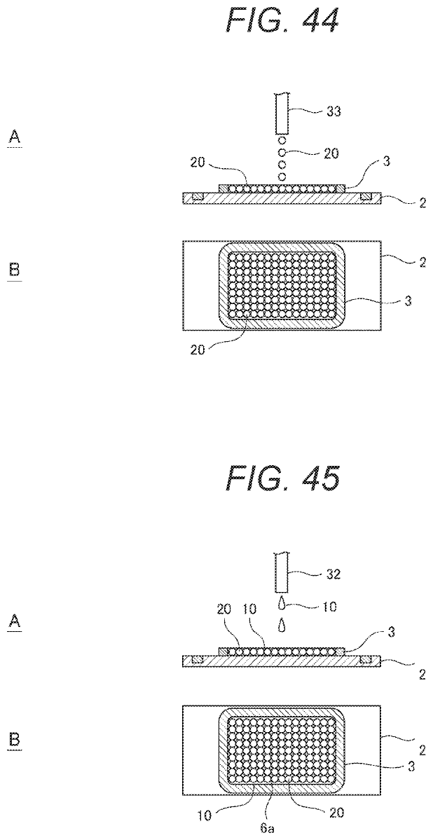

Next, as illustrated in FIG. 44, the metal-coated small spheres 20 are injected into a substantially square region formed by applying the adhesive 3 on the substrate 2 using the small sphere injection device 33.

Next, as illustrated in FIG. 45, the liquid metal 10 is injected into the substantially square region formed by applying the adhesive 3 on the substrate 2 using the liquid metal injection device 32. As a result, a large number of metal-coated small spheres 20 are sealed in the region surrounded by the adhesive 3 applied in the substantially square shape, and a gap 6a between the metal-coated small spheres 20 is filled with the liquid metal 10.

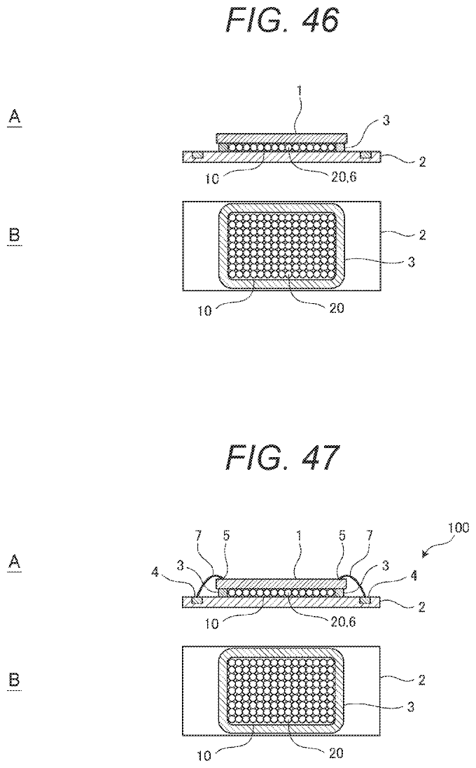

Next, as illustrated in FIG. 46, the semiconductor element 1 is placed on and adhered to an upper surface of the applied adhesive 3.

Next, in FIG. 47, in a manner similar to that described with reference to FIG. 14, sealing of the metal-coated small spheres 20 and assembly of the semiconductor device 100 are completed by performing connection by the bonding wire 7.

Through the above steps, adhesiveness between the semiconductor element 1 and the substrate 2 is maintained, and the metal-coated small spheres 20 disposed immediately below the semiconductor element 1 transfer heat generated by the semiconductor element 1 to the substrate 2. Similarly, the liquid metal 10 with which the gap 6a between the metal-coated small spheres 20 is filled transfers the heat generated by the semiconductor element 1 to the substrate 2. Therefore, a temperature rise of the semiconductor element 1 can be suppressed. Moreover, warpage of the semiconductor element 1 generated in a case where conventional metal paste is used can be prevented.

### [Second Example of Cooling Medium Sealing Step in Third Embodiment]

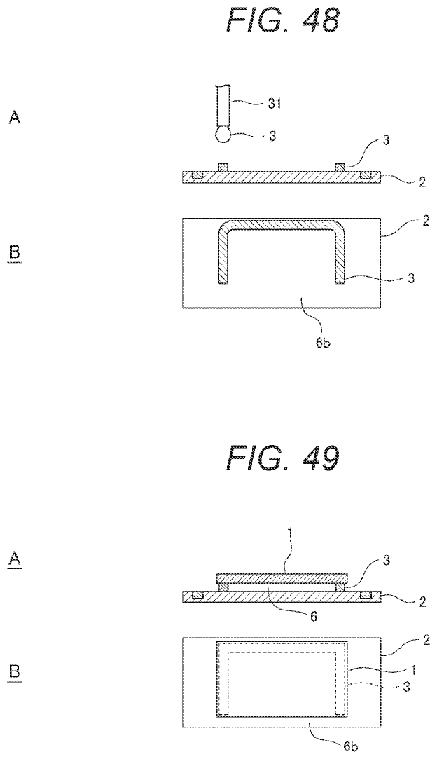

Next, description will be given of a second example of a cooling medium sealing step in the third embodiment of the semiconductor device 100 according to the present disclosure. FIGS. 48 to 53 are step explanatory views of the second example of the cooling medium sealing step in the present embodiment.

First, as illustrated in FIG. 48, the adhesive 3 is applied in a substantially C shape or a substantially U shape along the peripheral edge of the upper surface of the substrate 2 using the adhesive application device 31. That is, it is assumed that the adhesive 3 is not applied to one long side of the semiconductor element 1 as illustrated in this drawing.

Next, as illustrated in a sectional view and a plan view of an external appearance of FIG. 49, the semiconductor element 1 is placed on and adhered to an upper surface of the applied adhesive 3. With such adhesion, as illustrated in FIG. 49, three sides to which the adhesive 3 is applied in the substantially U shape are closed by the semiconductor element 1 and the substrate 2, and an opening 6b of the clearance 6 is formed on the long side of the semiconductor element 1 to which the adhesive 3 is not applied.

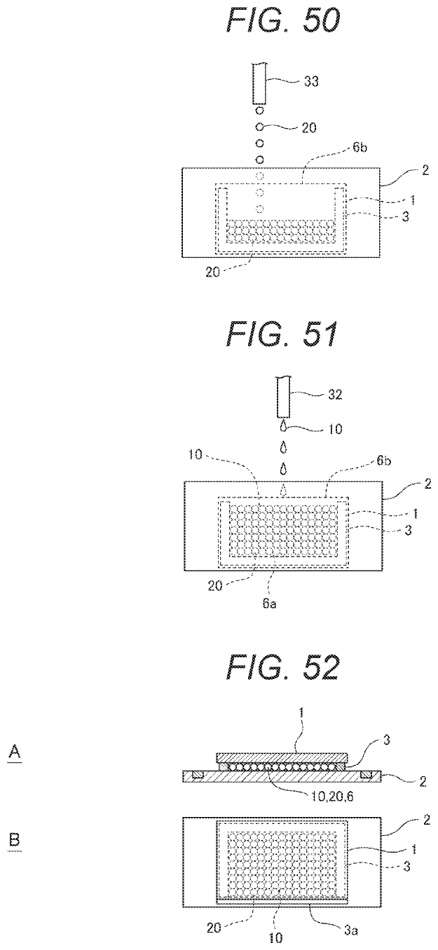

Next, as illustrated in FIG. 50, the semiconductor element 1 and the substrate 2 integrated by adhesion are inclined such that the opening 6b of the clearance 6 opened on the long side of the semiconductor element 1 faces upward, in a manner similar to that described with reference to FIG. 26. Then, the metal-coated small spheres 20 are injected into the clearance 6 between the semiconductor element 1 and the substrate 2 through the opening 6b of the clearance 6 using the small sphere injection device 33.

Next, as illustrated in FIG. 51, in a manner similar to that described with reference to FIG. 17, the liquid metal 10 is injected through the opening 6b using the liquid metal injection device 32. As a result, a large number of metal-coated small spheres 20 are injected into the clearance 6, and the gap 6a between the metal-coated small spheres 20 is filled with the liquid metal 10.

Next, the sealing adhesive 3a is applied to the opening 6b of the clearance 6. Therefore, as illustrated in a sectional view and a plan view of an external appearance in FIG. 52, the liquid metal 10 and the metal-coated small spheres 20 are sealed in the substantially square clearance 6 formed between the substrate 2 and the semiconductor element 1.

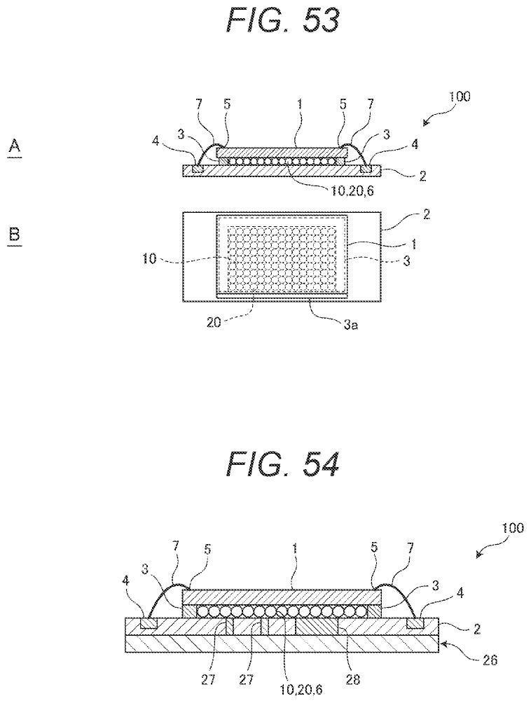

Next, in FIG. 53, in a manner similar to that described with reference to FIG. 14, sealing of the metal-coated small spheres 20 and assembly of the semiconductor device 100 are completed by performing connection by the bonding wire 7.

Through the above steps, adhesiveness between the semiconductor element 1 and the substrate 2 is maintained, and the metal-coated small spheres 20 disposed immediately below the semiconductor element 1 transfer heat generated by the semiconductor element 1 to the substrate 2. Similarly, the liquid metal 10 with which the gap 6a between the metal-coated small spheres 20 is filled transfers the heat generated by the semiconductor element 1 to the substrate 2. Therefore, a temperature rise of the semiconductor element 1 can be suppressed. Furthermore, other effects are similar to a case in the second example of the cooling medium sealing step in the first embodiment, and thus description thereof is omitted.

### [Third Example of Cooling Medium Sealing Step in Third Embodiment]

Next, description will be given of a third example of a cooling medium sealing step in the third embodiment of the semiconductor device 100 according to the present disclosure. The third example can be realized by adding a step of injecting the liquid metal 10 similar to that described in the step of FIG. 51 between the step of FIG. 32 and the step of FIG. 33 in the third example of the cooling medium sealing step in the second embodiment.

That is, after the step of FIG. 32, the semiconductor element 1 and the substrate 2 integrated by adhesion are inclined such that the opening 6b of the clearance 6 opened on the long side of the semiconductor element 1 faces upward. Then, the liquid metal 10 is injected through the opening 6b of the clearance 6 using the liquid metal injection device 32, and when the injection is completed, the opening 6b is sealed by applying the sealing adhesive 6a. As a result, a large number of metal-coated small spheres 20 are sealed in a substantially square region formed by applying the adhesive 3 on the substrate 2, and the gap 6a between the metal-coated small spheres 20 is filled with the liquid metal 10.

Furthermore, it can be realized by adding a step of injecting the liquid metal 10 similar to that described in the step of FIG. 45 between the step of FIG. 31 and the step of FIG. 32 in the third example of the cooling medium sealing step in the second embodiment.

Hereinafter, as illustrated in FIG. 33, by performing connection by the bonding wire 7 in the third example of the cooling medium sealing step in the second embodiment, sealing of the liquid metal 10 and the metal-coated small spheres 20 and assembly of the semiconductor device 100 are completed.

Effects of the third example are similar to those of the third example of the cooling medium sealing step in the second embodiment and the second example of the cooling medium sealing step in the third embodiment, and thus description thereof will be omitted.

### [Fourth Example of Cooling Medium Sealing Step in Third Embodiment]

Next, description will be given of a fourth example of a cooling medium sealing step in the third embodiment of the semiconductor device 100 according to the present disclosure. The fourth example can be realized by adding a step of injecting the liquid metal 10 similar to that described in the step of FIG. 51 between the step of FIG. 38 and the step of FIG. 39 in the fourth example of the cooling medium sealing step in the second embodiment.

That is, after the step of FIG. 38, the semiconductor element 1 and the substrate 2 integrated by adhesion are inclined such that the opening 6b of the clearance 6 opened on the long side of the semiconductor element 1 faces upward. Then, the liquid metal 10 is injected through the opening 6b of the clearance 6 using the liquid metal injection device 32, and when the injection is completed, the opening 6b is sealed by applying the sealing adhesive 6a. As a result, a large number of metal-coated small spheres 20 are sealed in a substantially square region formed by applying the adhesive 3 on the substrate 2, and the gap 6a between the metal-coated small spheres 20 is filled with the liquid metal 10.

Furthermore, it can be realized by adding a step of injecting the liquid metal 10 similar to that described in the step of FIG. 45 between the step of FIG. 37 and the step of FIG. 38 in the fourth example of the cooling medium sealing step in the second embodiment.

Hereinafter, as illustrated in FIG. 39, by performing connection by the bonding wire 7 in the fourth example of the cooling medium sealing step in the second embodiment, sealing of the liquid metal 10 and the metal-coated small spheres 20 and assembly of the semiconductor device 100 are completed.

Effects of the fourth example are similar to those of the fourth example of the cooling medium sealing step in the second embodiment and the second example of the cooling medium sealing step in the third embodiment, and thus description thereof will be omitted.

### <7. Fourth Embodiment of Semiconductor Device According to the Present Disclosure>

FIG. 54 is a sectional view of a fourth embodiment of a semiconductor device 100 according to the present disclosure. In the present embodiment, a heat exhausting mechanism 26 is added to any of the semiconductor devices 100 described in the first to third embodiments. That is, the heat exhausting mechanism 26 is further added to the semiconductor device 100 using a liquid metal 10, a metal-coated small sphere 20, or the liquid metal 10 and the metal-coated small sphere 20 as a cooling medium of a semiconductor element 1.

Specifically, as illustrated in FIG. 54, the heat exhausting mechanism 26 is disposed on a lower surface of the semiconductor device 100. The heat exhausting mechanism 26 is, for example, a heat slag or a Peltier element. In the substrate 2, a thermal via 27 and a copper inlay 28 are disposed immediately below a heat generating source of the semiconductor element 1. Then, the liquid metal 10, the metal-coated small sphere 20, and the like transfer heat of the semiconductor element 1 to the thermal via 27 and the copper inlay 28, and the thermal via 27 and the copper inlay 28 further transfer the heat to the heat exhausting mechanism 26. Therefore, heat can be transferred with high efficiency, so that a temperature rise of the semiconductor element 1 can be further suppressed.

### <8. Cooling Medium Sealing Structure of Semiconductor Device According to the Present Disclosure>

The semiconductor device 100 and the cooling medium sealing step according to the present disclosure are configured as described above. However, in a case where the cooling medium is sealed in the clearance 6 between the semiconductor element 1 and the substrate 2, there is a possibility that the following problems occur.

Part 1 is a case where an amount of the cooling medium is too small. In this case, since air is interposed in the clearance 6 between the semiconductor element 1 and the substrate 2 and a position of the air cannot be specified, thermal conductivity decreases or varies, and an effect of suppressing a temperature rise is inhibited. Part 2 is a case where the amount of the cooling medium is too large. In this case, there is a possibility that the cooling medium expands due to an increase in ambient temperature or heat generation of the semiconductor element 1, and peeling or cracking of the adhesive 3 occurs due to stress thereof. The metal-coated small sphere 20 has elasticity and is not likely to be peeled or cracked when subjected to an external force. However, in a case of the liquid metal 10, volume thereof expands or contracts, which is problematic.

Therefore, as a countermeasure against the problem in the case of the liquid metal 10, the clearance 6 between the semiconductor element 1 and the substrate 2 desirably has the following configuration.

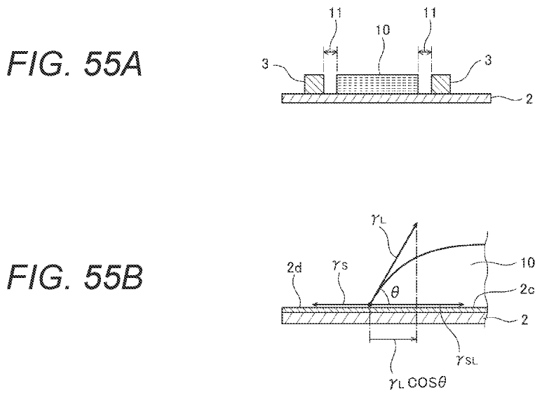

First, Part 1 is a configuration using surface tension as illustrated in FIG. 55. In FIG. 55A, a space 11 for air is formed between the adhesive 3 and the liquid metal 10 in the clearance 6 (In the drawing, the semiconductor element 1 is not illustrated.). By forming such a space 11, the liquid metal 10 can be in close contact with the lower surface of the semiconductor element 1 disposed on an upper portion of the adhesive 3 by maintaining a height thereof. Note that this is a countermeasure in the first embodiment and the third embodiment of the semiconductor device 100 according to the present disclosure.

Here, in a case where the volume of the liquid metal 10 expands due to a temperature rise, the liquid metal 10 extends in a plane direction in the clearance 6, and thus compresses air in the space 11. As the air is compressed, the volume decreases and air pressure increases. However, the increase in the air pressure in the space 11 due to the compression of the air is not large enough to cause peeling or cracking of the adhesive 3.

On the other hand, in a case where the temperature decreases, the volume of the liquid metal 10 contracts, and the air in the space 11 is decompressed. The air pressure in the space 11 decreases by being decompressed, but similarly, this case also does not cause a problem. Here, in a case where the surface tension of the liquid metal 10 is too small, there can be a problem that the space 11 as illustrated in FIG. 55A cannot be formed.

Therefore, use of surface tension will be described in more detail. FIG. 55B is an explanatory view of an equilibrium state of the surface tension. In the drawing, surface tension of a surface 2c of the substrate 2 onto which the liquid metal 10 is dropped is represented by γ_{SL}, surface tension of a surface 2d of the substrate 2 onto which the liquid metal 10 is not dropped is represented by γ_{S}, and surface tension of the liquid metal 10 is represented by γ_{L}. When the liquid metal 10 maintains a state in the drawing,

the following Young's equation holds.

γ_{S}=γ_{L}×cos θ+γ_{SL}

A condition for satisfying this equation is γ_{L}>γ_{S}. That is, a phenomenon in which the liquid is repelled and becomes substantially spherical occurs in a case where the surface tension γ_{S} of the solid surface is smaller than the surface tension γ_{L} of the liquid. That is, in order to make the surface 2d of the substrate 2 substantially spherical by repelling the liquid metal 10, the liquid metal 10 having the surface tension γ_{L} larger than the surface tension γ_{S} of the surface 2 is only required to be used. For example, mercury has an extremely large surface tension value of 485.5 mN/m, and thus has a substantially spherical shape. Therefore, the space 11 can be easily formed.

Conversely, the surface tension of the surface 2d of the substrate 2 is only required to made smaller than the surface tension of the liquid metal 10 as a countermeasure in a case where the liquid metal 10 having no large surface tension like mercury is used. For example, it is effective to coat the surface 2d of the substrate 2 with a fluorine-based material (10 to 25 mN/m) containing a Teflon (registered trademark)-based material having small surface tension. By performing such a treatment, the liquid metal 10 having surface tension larger than that of the surface 2d is repelled by fluorine-based coating to be in close contact with the lower surface of the semiconductor element 1 in a state where the space 11 is formed, and heat can be transferred. Note that the coating may be applied to the lower surface of semiconductor element 1 facing the surface 2d. Alternatively, it may be applied to both the surface 2d of the substrate 2 and the lower surface of semiconductor element. Furthermore, there is a possibility that one having a large surface tension can be formed by changing a component ratio of gallium, indium, and the like as Galinstan of the liquid metal 10.

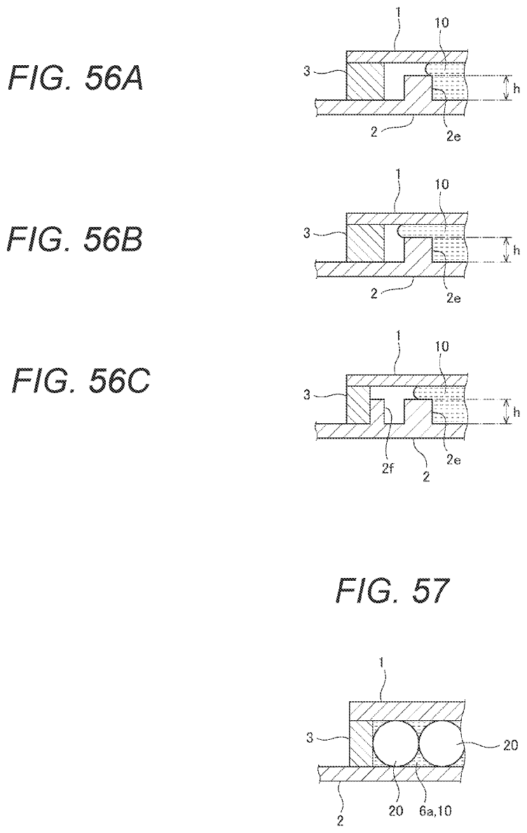

Next, a countermeasure for forming a partition 2e in the clearance 6 surrounded by the adhesive 3 will be described. FIG. 56A is an explanatory view in which a space 11 is formed by providing the partition 2e in the clearance 6. In this drawing, the substantially protruded partition 2e having a height h slightly lower than the height of the adhesive 3 is provided in a protruding manner on the substrate 2 in the vicinity of an inner side to which the adhesive 3 is applied. With such a configuration, the liquid metal 10 can be sandwiched between the semiconductor element 1 and the substrate 2 to form the space 11 with the adhesive 3.

Since the liquid metal 10 is sandwiched between an upper surface of the partition 2e and a lower surface of the semiconductor element 1, the liquid metal does not spill out of the partition 2e due to surface tension. Incidentally, since the liquid metal 10 contracts in a low temperature state, the liquid metal 10 side is drawn into the partition 2e as illustrated in FIG. 56A. Furthermore, since the liquid metal 10 expands in a high temperature state, the liquid metal 10 comes out of the partition 2e as illustrated in FIG. 56B.

However, when an injection amount of the liquid metal 10 is too large, there is a possibility that the liquid metal overflows into the space 11 due to expansion, and thus it is necessary to adjust the injection amount to an appropriate amount. Note that in a case where the height h of the partition 2e is 0 (zero), the space 11 using the surface tension illustrated in FIG. 55A is obtained.

Furthermore, as illustrated in FIG. 56C, another partition 2f having substantially the same height as the partition 2e or substantially the same height as the adhesive 3 may protrude between the adhesive 3 applied onto the substrate 2 and the protruded partition 2e. With such a configuration, the liquid metal 10 can be sandwiched between the semiconductor element 1 and the substrate 2 to form the space 11 with the adhesive 3.

Note that the height and width of each of the partitions 2e and 2f are not limited to those in the above-described example, and it goes without saying that any combination can be used.

Next, Part 2 of the countermeasure against the problem in the case of the liquid metal 10 is for a configuration in which the liquid metal is used in combination with the metal-coated small sphere 20 as illustrated in FIG. 57. This is a countermeasure in the third embodiment according to the present disclosure. Specifically, as illustrated in this drawing, the gap 6a between the metal-coated small spheres 20 sealed in the clearance 6 is only required to be completely filled with the liquid metal 10. With such a configuration, the liquid metal 10 can be sandwiched between the semiconductor element 1 and the substrate 2 to form a thermal conductor with the adhesive 3. Even if the liquid metal 10 expands or contracts due to a temperature change, the metal-coated small spheres 20 are deformed in response to the expansion or contraction, so that a package is not cracked due to an increase in internal pressure of the clearance 6. As described above, by combining the liquid metal 10 and the metal-coated small spheres 20, the metal-coated small spheres 20 alleviate a change in pressure accompanying the expansion and contraction of the liquid metal 10, and adjustment accompanying the expansion and contraction can be automatically performed. Also, this configuration is the simplest and reliable, and does not need to consider surface tension and the like, and thus has a large effect.

Although the countermeasures for the problems have been described above, these may be appropriately combined.

### <9. Electronic Apparatus Including Semiconductor Device According to the Present Disclosure>

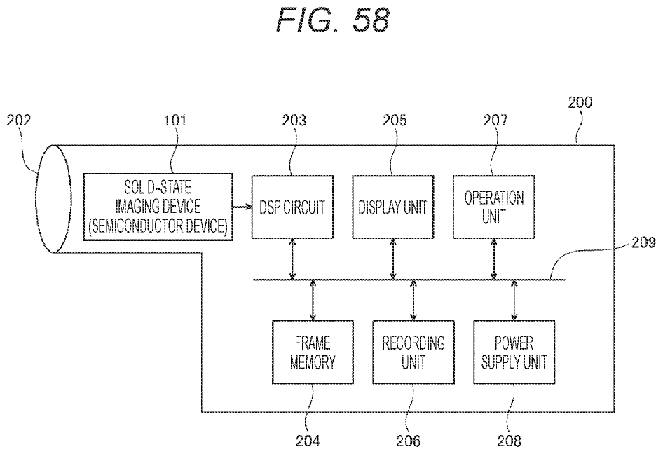

A configuration example of an electronic apparatus including the solid-state imaging device 101 as an example of the semiconductor devices 100 according to the first to fourth embodiments will be described with reference to FIG. 58.

The semiconductor device 100 according to the present disclosure can be applied to an imaging device such as a digital still camera, a video camera, and the like, a mobile terminal device having an imaging function, or an imaging apparatus such as a copier using the solid-state imaging device 101 as an image reading unit. Furthermore, application thereof is not limited to the imaging device, and can be widely applied to a general electronic apparatus such as an industrial apparatus including an electric home appliance, a communication apparatus, and an in-vehicle apparatus. Note that the solid-state imaging device 101 may be a CMOS sensor or a CCD sensor. Furthermore, the solid-state imaging device 101 may be formed as one chip, or may be in the form of a module having an imaging function in which an imaging unit and a signal processing unit or an optical system are packaged together, as long as the cooling medium according to the present disclosure is included.

As illustrated in FIG. 58, an imaging apparatus 200 as an electronic apparatus includes an optical unit 202, the solid-state imaging device 101, a digital signal processor (DSP) circuit 203 which is a camera signal processing circuit, a frame memory 204, a display unit 205, a recording unit 206, an operation unit 207, and a power supply unit 208. The DSP circuit 203, the frame memory 204, the display unit 205, the recording unit 206, the operation unit 207, and the power supply unit 208 are connected to one another through a bus line 209.

The optical unit 202 includes a plurality of lenses, and captures incident light (image light) from a subject to form an image on a pixel region (not illustrated) of the solid-state imaging device 101. The solid-state imaging device 101 converts a light amount of the incident light imaged on the pixel region thereof by the optical unit 202 into an electric signal in a pixel unit to output as a pixel signal.

The display unit 205 including a panel display device such as a liquid crystal panel, an organic electro luminescence (EL) panel, and the like, for example, displays a moving image or a still image taken by the solid-state imaging device 101. The recording unit 206 records the moving image or the still image captured by the solid-state imaging device 101 on a recording medium such as a hard disk, a semiconductor memory, and the like.

The operation unit 207 issues operation commands for various functions of the imaging apparatus 200 under operation by the user. The power supply unit 208 appropriately supplies various power sources serving as operation power sources of the DSP circuit 203, the frame memory 204, the display unit 205, the recording unit 206, and the operation unit 207 to these supply targets.

Furthermore, the semiconductor device 100 according to the present disclosure can be widely applied not only to the solid-state imaging device 101 but also to various semiconductor devices 100 constituting circuits such as the DSP circuit 203, the frame memory 204, the recording unit 206, the display unit 205, the operation unit 207, and the like.

As described above, according to the present disclosure, by using the solid-state imaging device 101 which is the semiconductor device 100 according to the present disclosure, it is possible to obtain the highly reliable imaging apparatus 200 having excellent heat dissipation.

Finally, the description of each of the above-described embodiments is an example of the present disclosure, and the present disclosure is not limited to the above-described embodiments. For this reason, it is needless to say that various modifications other than the above-described embodiments can be made according to the design and the like without departing from the technical idea according to the present disclosure. Furthermore, the effects described in the present specification are merely examples and are not limited, and other effects may be provided.

Note that the present technology can also have the following configuration.

(1)

A semiconductor device including:
a semiconductor element;
a substrate to which the semiconductor element is fixed; and
a cooling medium with which a clearance formed when the semiconductor element and the substrate are fixed to each other is filled.

(2)

The semiconductor device according to (1), in which the cooling medium is a liquid metal.

(3)

The semiconductor device according to (1), in which the cooling medium is a metal-coated small sphere.

(4)

The semiconductor device according to (1), in which the cooling medium is a liquid metal and a metal-coated small sphere.

(5)

The semiconductor device according to any one of (1) to (4), in which the cooling medium with which the clearance is filled is disposed below a heat generating source of the semiconductor element.

(6)

The semiconductor device according to any one of (1) to (5), in which the clearance is formed by the substrate, the semiconductor element, and an adhesive applied to an entire peripheral edge of the semiconductor element to fix both the substrate and the semiconductor element, and an upper surface of the substrate is covered with a low surface tension material along an inner periphery of the adhesive.

(7)

The semiconductor device according to any one of (1) to (5), in which the clearance is formed by the substrate, the semiconductor element, and an adhesive applied to an entire peripheral edge of the semiconductor element to fix both the substrate and the semiconductor element, and a partition having a height lower than a thickness height of the adhesive protrudes from an upper surface of the substrate along an inner periphery of the adhesive.

(8)

The semiconductor device according to any one of (1) to (4), further including a heat exhausting mechanism on a lower surface of the substrate.

(9)

A method for manufacturing a semiconductor device, including:
applying an adhesive in such a manner as to surround a region on a substrate where a cooling medium is disposed;
injecting the cooling medium into a region surrounded by the adhesive; and
adhering a semiconductor element onto the adhesive.

(10)

The method for manufacturing the semiconductor device according to (9), in which the cooling medium injected into the surrounded region is a liquid metal.

(11)

The method for manufacturing the semiconductor device according to (9), in which the cooling medium injected into the surrounded region is a metal-coated small sphere.

(12)

The method for manufacturing the semiconductor device according to (9), in which the cooling medium injected into the surrounded region is a liquid metal and a metal-coated small sphere.

(13)

A method for manufacturing a semiconductor device, including:
applying an adhesive in such a manner as to surround a region on a substrate where a cooling medium is disposed;
adhering a semiconductor element onto the adhesive;
injecting the cooling medium into a clearance formed by the substrate, the adhesive, and the semiconductor element; and
sealing the clearance.

(14)

The method for manufacturing the semiconductor device according to (13), in which the cooling medium injected into the clearance is a liquid metal.

(15)

The method for manufacturing the semiconductor device according to (13), in which the cooling medium injected into the clearance is a metal-coated small sphere.

(16)

The method for manufacturing the semiconductor device according to (13), in which the cooling medium injected into the clearance is a liquid metal and a metal-coated small sphere.

(17)

A method for manufacturing a semiconductor device, including:
placing metal-coated small spheres on a plurality of recesses provided on a substrate;
applying an adhesive in such a manner as to surround the placed metal-coated small spheres; and adhering a semiconductor element onto the adhesive.

(18)

A method for manufacturing a semiconductor device, including:
placing metal-coated small spheres on a plurality of soldering pads disposed on a substrate;
soldering the placed metal-coated small spheres;
applying an adhesive in such a manner as to surround the placed metal-coated small spheres; and
adhering a semiconductor element onto the adhesive.

(19)

A method for manufacturing a semiconductor device, including:
placing metal-coated small spheres on a plurality of soldering pads disposed on a lower surface of a semiconductor element;
soldering the placed metal-coated small spheres;
applying an adhesive to the substrate or the lower surface of the semiconductor element in such a manner as to surround the metal-coated small spheres when the surface of the semiconductor element to which the metal-coated small spheres are soldered is placed on the substrate; and
adhering the surface of the semiconductor element to which the metal-coated small spheres are soldered onto the adhesive.

(20)

The method for manufacturing the semiconductor device according to any one of (17) to (19), further including: injecting a liquid metal into a clearance formed by the substrate, the semiconductor element, and the adhesive applied in such a manner as to surround the metal-coated small spheres.

(21)

An electronic apparatus having a semiconductor device including:
a semiconductor element;
a substrate to which the semiconductor element is fixed; and
a cooling medium with which a clearance formed when the semiconductor element and the substrate are fixed to each other is filled.

### REFERENCE SIGNS LIST

1 Semiconductor element
1b Soldering pad
2 Substrate
2a Recess
2b Soldering pad
2c Surface
2d Surface
2e Partition
2f Partition
3 Adhesive
3a Sealing adhesive
4 Substrate pad
5 Electrode pad
6 Clearance
6a Gap
6b Opening
7 Bonding wire
10 Liquid metal
11 Space
20 Metal-coated small sphere
21 Core
22 Polyimide film
23 Metal film
26 Heat exhausting mechanism
27 Thermal via
28 Copper inlay
31 Adhesive application device
32 Liquid metal injection device
33 Small sphere injection device
34 Small sphere placing jig
35 Metal mask
35a Mask hole
36 Squeegee
37 Soldering jig
40 Cream solder
100 Semiconductor device
101 Solid-state imaging device
200 Imaging apparatus

What is claimed is:

1. A semiconductor device, comprising:
a semiconductor element;
a substrate to which the semiconductor element is fixed; and
a cooling medium with which a clearance formed when the semiconductor element and the substrate are fixed to each other is filled.

2. The semiconductor device according to claim 1, wherein the cooling medium is a liquid metal.

3. The semiconductor device according to claim 1, wherein the cooling medium is a metal-coated small sphere.

4. The semiconductor device according to claim 1, wherein the cooling medium is a liquid metal and a metal-coated small sphere.

5. The semiconductor device according to claim 1, wherein the cooling medium with which the clearance is filled is disposed below a heat generating source of the semiconductor element.

6. The semiconductor device according to claim 1, wherein the clearance is formed by the substrate, the semiconductor element, and an adhesive applied to an entire peripheral edge of the semiconductor element to fix both the substrate and the semiconductor element, and an upper surface of the substrate is covered with a low surface tension material along an inner periphery of the adhesive.

7. The semiconductor device according to claim 1, wherein the clearance is formed by the substrate, the semiconductor element, and an adhesive applied to an entire peripheral edge of the semiconductor element to fix both the substrate and the semiconductor element, and a partition having a height lower than a thickness height of the adhesive protrudes from an upper surface of the substrate along an inner periphery of the adhesive.

8. The semiconductor device according to claim 1, further comprising a heat exhausting mechanism on a lower surface of the substrate.

9. A method for manufacturing a semiconductor device, comprising:
applying an adhesive in such a manner as to surround a region on a substrate where a cooling medium is disposed;
injecting the cooling medium into a region surrounded by the adhesive; and
adhering a semiconductor element onto the adhesive.

10. The method for manufacturing the semiconductor device according to claim 9, wherein the cooling medium injected into the surrounded region is a liquid metal.

11. The method for manufacturing the semiconductor device according to claim 9, wherein the cooling medium injected into the surrounded region is a metal-coated small sphere.

12. The method for manufacturing the semiconductor device according to claim 9, wherein the cooling medium injected into the surrounded region is a liquid metal and a metal-coated small sphere.

13. A method for manufacturing a semiconductor device, comprising:
applying an adhesive in such a manner as to surround a region on a substrate where a cooling medium is disposed;
adhering a semiconductor element onto the adhesive;
injecting the cooling medium into a clearance formed by the substrate, the adhesive, and the semiconductor element; and
sealing the clearance.

14. The method for manufacturing the semiconductor device according to claim 13, wherein the cooling medium injected into the clearance is a liquid metal.

15. The method for manufacturing the semiconductor device according to claim 13, wherein the cooling medium injected into the clearance is a metal-coated small sphere.

16. The method for manufacturing the semiconductor device according to claim 13, wherein the cooling medium injected into the clearance is a liquid metal and a metal-coated small sphere.

17. A method for manufacturing a semiconductor device, comprising:
placing metal-coated small spheres on a plurality of recesses provided on a substrate;
applying an adhesive in such a manner as to surround the disposed metal-coated small spheres; and
adhering a semiconductor element onto the adhesive.

18. A method for manufacturing a semiconductor device, comprising:
placing metal-coated small spheres on a plurality of soldering pads disposed on a substrate;
soldering the placed metal-coated small spheres;
applying an adhesive in such a manner as to surround the placed metal-coated small spheres; and
adhering a semiconductor element onto the adhesive.

19. A method for manufacturing a semiconductor device, comprising:
placing metal-coated small spheres on a plurality of soldering pads disposed on a lower surface of a semiconductor element;
soldering the placed metal-coated small spheres;
applying an adhesive to the substrate or the lower surface of the semiconductor element in such a manner as to surround the metal-coated small spheres when the surface of the semiconductor element to which the metal-coated small spheres are soldered is placed on the substrate; and
adhering the surface of the semiconductor element to which the metal-coated small spheres are soldered onto the adhesive.

20. The method for manufacturing the semiconductor device according to claim 17, further comprising: injecting a liquid metal into a clearance formed by the substrate, the semiconductor element, and the adhesive applied in such a manner as to surround the metal-coated small spheres.

21. An electronic apparatus having a semiconductor device, comprising:
a semiconductor element;
a substrate to which the semiconductor element is fixed; and
a cooling medium with which a clearance formed when the semiconductor element and the substrate are fixed to each other is filled.
